(19) United States
(12) Patent Application Publication
(10) Pub. No.: US 2025/0255025 A1
(43) Pub. Date: Aug. 7, 2025

(54) IMAGE SENSOR AND METHOD FOR FABRICATING THE SAME

(71) Applicant: Samsung Electronics Co., Ltd., Suwon-si (KR)

(72) Inventors: Kook Tae KIM, Suwon-si (KR); Seunghwi YOO, Suwon-si (KR); Minkyung LEE, Suwon-si (KR); Jingyun KIM, Suwon-si (KR)

(73) Assignee: Samsung Electronics Co., Ltd., Suwon-si (KR)

(21) Appl. No.: 18/820,451

(22) Filed: Aug. 30, 2024

(30) Foreign Application Priority Data
Feb. 6, 2024 (KR) 10-2024-0018275

(51) Int. Cl. H01L 27/146

(52) U.S. Cl. CPC H10F 39/807; H10F 39/011; H10F 39/8063; H10F 39/811

(57) ABSTRACT

An image sensor includes a semiconductor substrate including a plurality of pixels and having a first surface and a second surface opposite to the first surface, the semiconductor substrate having a trench formed through the first surface and the second surface; a micro-lens on the second surface; an isolation layer in the trench that isolates the pixels from each other; and an etching barrier layer in the isolation layer and having a first depth from the first surface. The etching barrier layer has a corrosion resistance higher than a corrosion resistance of a region of the semiconductor substrate other than the etching barrier layer.

### CROSS-REFERENCE TO RELATED APPLICATIONS

This application claims priority under 35 U.S.C. § 119 to Korean Patent Application No. 10-2024-0018275 filed on Feb. 6, 2024, in the Korean Intellectual Property Office, the disclosure of which is incorporated by reference herein in its entirety.

### BACKGROUND

Some example embodiments of the present disclosure described herein relate to image sensors and methods for fabricating the same.

An image sensor includes a plurality of pixels arranged in two dimensions. Each pixel includes a photodiode (PD) serving as a photoelectric conversion element. An isolation layer is formed between photoelectric conversion elements to isolate the photoelectric conversion elements from each other. The isolation layer may absorb light depending on materials. Accordingly, when the light is absorbed at a light incident side, the photoelectric conversion elements are reduced in an amount of light incident thereto.

### SUMMARY

Some example embodiments of the present disclosure enhance photoelectric conversion efficiency by reducing (and/or minimizing) light loss in an image sensor.

Some example embodiments of the present disclosure improve the quality of an image sensor by limiting and/or preventing a material constituting an isolation layer from being lost in the process of fabricating the image sensor.

Some example embodiments of the present disclosure provide an image sensor that includes a semiconductor substrate including a plurality of pixels, the semiconductor substrate having a first surface and a second surface opposite to the first surface, and the semiconductor substrate having a trench formed through the first surface and the second surface; an isolation layer in the trench that isolates the pixels from each other; and an etching barrier layer in the isolation layer, the etching barrier layer having a first depth from the first surface of the semiconductor substrate. The isolation layer including an insulating liner covering a sidewall of the trench, the insulation liner passing from the first surface to the second surface; a support covering at least a portion of a sidewall of the insulating liner; and a conductive liner inside the trench, the conductive liner contacting the insulating liner and the support. The etching barrier layer has a corrosion resistance higher than a corrosion resistance of a region of the semiconductor substrate other than the etching barrier layer.

According to some example embodiments of the present disclosure, the isolation layer may include an insulating material in a region adjacent to the first surface, and the etching barrier layer may include the insulating material having impurities doped therein.

According to some example embodiments of the present disclosure, the impurities may include at least one of B, C, N, Ar, He, Si, As, P, BF₂, BF₃, or Sb.

According to some example embodiments of the present disclosure, the impurities may have a doping concentration ranging from 1.0×10¹⁴/cm² to 2.0×10¹⁶/cm².

According to some example embodiments of the present disclosure, the etching barrier layer may have a thickness ranging from 1 Å to 1800 Å.

According to some example embodiments of the present disclosure, the image sensor may further include a shallow isolation layer buried into the semiconductor substrate while extending from the first surface, and the etching barrier layer may be provided to have 70% or less of a depth of the shallow isolation layer.

According to some example embodiments of the present disclosure, the insulating liner and the support may include the insulating material, and the etching barrier layer may be in a portion of the insulating liner and a portion of the support.

According to some example embodiments of the present disclosure, a sum of a width of the insulating liner adjacent to the first surface and a width of the support, may be greater than a width of the insulating liner adjacent to the second surface.

According to some example embodiments of the present disclosure, the plurality of pixels may be arranged in a form of a matrix in a plan view, and the isolation layer may include a first isolation layer at side parts of the plurality of pixels, the side parts extending in a row direction and a column direction of the matrix; and a second isolation layer at crossing parts at which the side parts cross each other along the row and column directions.

According to some example embodiments of the present disclosure, the conductive liner at the second isolation layer may include respective second conductive liners that surround peripheral portions of respective pixels from among the plurality of pixels, the respective second conductive liners being spaced apart from each other between pixels from among the plurality of pixels that are adjacent to each other, and the conductive liner at the first isolation layer may include respective first conductive liners that surround peripheral portions of respective pixels from among the plurality of pixels, the respective first conductive liners being connected to each other between pixels from among the plurality of pixels that are adjacent to each other.

According to some example embodiments of the present disclosure, the conductive liner may be connected to a negative bias voltage.

According to some example embodiments of the present disclosure, the image sensor may further include a buried insulating pattern filled in the trench, the buried insulating pattern covering the conductive liner and the support.

According to some example embodiments of the present disclosure, the buried insulating pattern may define a cavity therein, and the cavity may be filled with at least one of air and the insulating material.

According to some example embodiments of the present disclosure, the insulating material filled in the cavity may be at least one of hafnium oxide, zirconium oxide, titanium oxide, aluminum oxide, silicon oxide, tantalum oxide, or plasma enhanced-tetra ethylene orthosilicate.

According to some example embodiments of the present disclosure, the image sensor may further include a buried conductive pattern filled in the trench, the buried conductive pattern covering the conductive liner and the support.

According to some example embodiments of the present disclosure, the buried conductive pattern may be in the second isolation layer.

According to some example embodiments of the present disclosure, a method for fabricating an image sensor may include preparing a semiconductor substrate having a first surface and a second surface opposite to the first surface, and a photoelectric conversion region in the semiconductor substrate; forming a trench through the first surface and the second surface of the semiconductor substrate; forming an insulating liner in the trench; forming a support in the trench on the insulating liner; forming a conductive liner in the trench, the conductive liner covering the support; filling a buried insulating pattern or a buried conductive pattern in the trench on the conductive liner; removing a portion of the insulating liner, the support, and the burred insulating pattern or the buried conductive pattern; forming an etching barrier layer by implanting impurities into remaining portions of the insulating liner, the support, and the buried insulating pattern or the buried conductive pattern; and etching a portion of the semiconductor substrate including the etching barrier layer.

According to some example embodiments of the present disclosure, the method may further include performing an annealing treatment on the etching barrier layer implanted with the impurities.

According to some example embodiments of the present disclosure, the forming of the etching barrier layer by implanting the impurities may include forming a photoresist pattern on at least a portion of the semiconductor substrate; and implanting the impurities using the photoresist pattern as a mask.

### BRIEF DESCRIPTION OF THE FIGURES

The above and other objects and features of the present disclosure will become apparent by describing in detail embodiments thereof with reference to the accompanying drawings.

FIG. 1 is a block diagram of an image sensor according to some example embodiments of the present disclosure.

FIG. 2 is a circuit diagram of a pixel array of an image sensor according to some example embodiments of the present disclosure.

FIG. 3 is a plan view of an image sensor according to some example embodiments of the present disclosure.

FIG. 4 is a cross-sectional view corresponding to line I-I′ of FIG. 3.

FIGS. 5A and 5B are cross-sectional views illustrating parts P1 and P2 of FIG. 4, in which FIG. 5A illustrates an isolation layer of a side part, and FIG. 5B illustrates an isolation layer of a crossing part.

FIGS. 6A and 6B are cross-sectional views illustrating parts corresponding to parts P1 and P2 of FIG. 4, in the image sensor according to some example embodiments of the present disclosure.

FIGS. 7A and 7B are cross-sectional views illustrating parts corresponding to parts P1 and P2 of FIG. 4, in the image sensor according to some example embodiments of the present disclosure.

FIGS. 8A and 8B are cross-sectional views illustrating parts corresponding to parts P1 and P2 of FIG. 4, in the image sensor according to some example embodiments of the present disclosure.

FIGS. 9A, 9B, 9C, 9D, 9E, 9F, 9G, 9H, 9I and 9J are sectional views sequentially illustrating a process of fabricating the image sensor according to some example embodiments of the present disclosure, and views corresponding to parts P1 and P2 of FIG. 4.

FIGS. 10A and 10B illustrate that impurities are locally doped only into a partial region, instead of that impurities are doped into the entire surface of the semiconductor substrate, in which FIG. 10A is a plan view illustrating four pixels adjacent to each other, and FIG. 10B are cross-sectional views taken along line A-A′ and B-B′ of FIG. 10A.

FIGS. 11A and 11B illustrate that impurities are locally doped only into a partial region, instead of that the impurities are doped into the entire surface of the semiconductor substrate, in which FIG. 11A is a plan view illustrating four pixels adjacent to each other, and FIG. 11B are cross-sectional views taken along line A-A′ and B-B′ of FIG. 11A.

FIGS. 12A and 12B illustrate that impurities are locally doped only into a partial region, instead of that impurities are doped into the entire surface of a semiconductor substrate, in which FIG. 12A is a plan view illustrating four pixels adjacent to each other, and FIG. 12B are cross-sectional views taken along line A-A′ and B-B′ of FIG. 12A.

FIGS. 13A, 13B, 13C, 13D and 13E are graphs illustrating the etch rate when impurities are doped into the insulating material constituting the insulating layer.

### DETAILED DESCRIPTION

While the present disclosure is susceptible to various modifications and alternative forms, specific embodiments thereof are shown by way of example in the drawings and will be described herein in detail. It should be understood, however, that there is no intent to limit the present disclosure to the particular forms disclosed, but on the contrary, the present disclosure is to cover all modifications, equivalents, and alternatives falling within the spirit and scope of the present disclosure.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

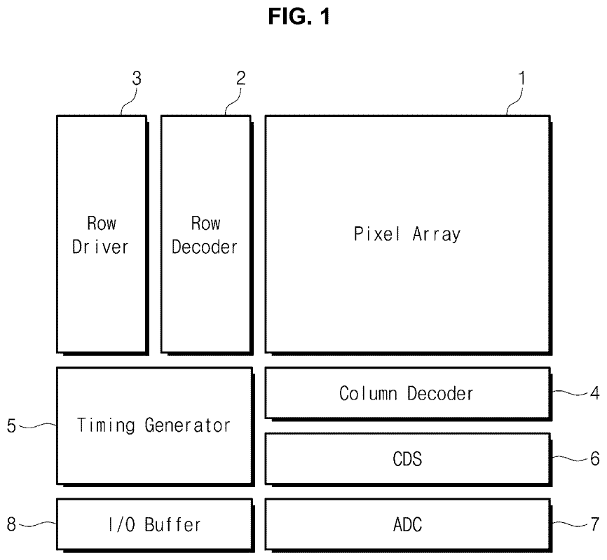

FIG. 1 is a block diagram schematically illustrating an image sensor according to some example embodiments of the present disclosure.

Referring to FIG. 1, an image sensor according to some example embodiments of the present disclosure includes a pixel array 1, a row decoder 2, a row driver 3, a column decoder 4, a timing generator 5, a correlated double sampler (CDS) 6, an analog to digital converter (ADC) 7, and an input/output (I/O) buffer 8.

The pixel array 1 includes a plurality of pixels arranged in two dimensions, to convert an optical signal into an electrical signal. The pixel array 1 may be driven in response to a plurality of driving signals, such as a pixel selecting signal, a reset signal, and a charge transfer signal. The converted electrical signal is provided to the CDS 6.

The row driver 3 provides, to the pixel array 1, a plurality of driving signals for driving a plurality of pixels, based on a decoding result from the row decoder 2. When the pixels are arranged in the form of a matrix, the driving signals may be provided for each row.

The timing generator 5 provides a timing signal and a control signal to the row decoder 2 and the column decoder 4.

The CDS 6 receives the electrical signal generated from the pixel array 1, holds the electrical signal, and performs sampling for the electrical signal. The CDS 6 doubly performs the sampling with respect to a specific noise level and a signal level by the electrical signal to output a difference level corresponding to the noise level and the signal level.

The ADC 7 converts the analog signal corresponding to the difference level output from the CDS 6 into a digital signal to be output.

The I/O buffer 8 latches the digital signal and sequentially outputs the digital signal to an image signal processing unit (not illustrated) based on the decoding result from the column decoder 4.

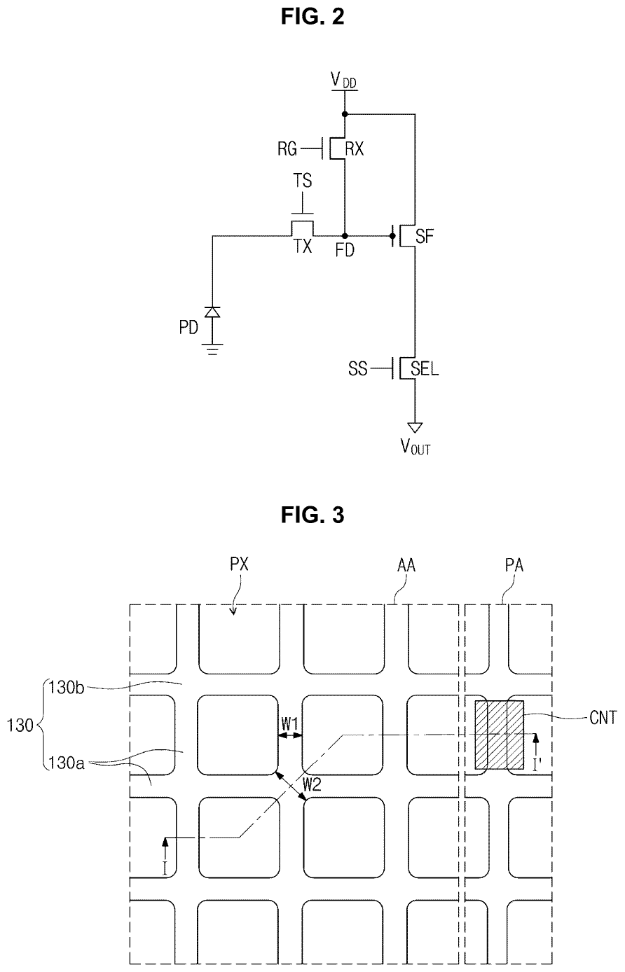

FIG. 2 is a circuit diagram of a pixel array of an image sensor according to some example embodiments of the present disclosure.

Referring to FIG. 2, the image sensor, which includes at least one pixel, may include a photoelectric conversion element PD and a plurality of transistors provided for each pixel.

The plurality of transistors may include a transfer transistor TX, a reset transistor RX, a source follower transistor SF, and a selection transistor SEL. According to some example embodiments of the present disclosure, although one transfer transistor is illustrated, a plurality of transistors may be provided.

The photoelectric conversion element PD may generate charges depending on the intensity of the incident light. For example, each of the photoelectric conversion elements PD, which serve as P-N junction diodes, may generate charges (that is, electrons serving as negative charges and holes serving as positive charges). Each of the photoelectric conversion elements PD may correspond to at least one of a photo transistor, a photo gate, a pinned photo diode (PPD), and the combination thereof.

The transfer transistor TX may transfer the charges, which are generated from the photoelectric conversion elements PD, into a floating diffusion region FD, in response to a transfer control signal TS. The floating diffusion region FD may receive the charges generated from the photoelectric conversion element PD and accumulate the charges.

Each of the reset transistors RX may be controlled in response to a reset control signal RG. The reset transistor RX may periodically reset charges accumulated in the floating diffusion region FD. A drain electrode of the reset transistor RX may be connected to the floating diffusion region FD, and a source electrode of the reset transistor RX may be connected to a power supply voltage VDD. When the reset transistor RX is turned on, the power supply voltage VDD of a supply terminal connected to the source electrode of the reset transistor RX may be applied to the floating diffusion region FD. Accordingly, when the reset transistor RX is turned on, the charges accumulated in the floating diffusion region FD may be discharged such that the floating diffusion region FD is reset.

The source follower transistor SF may correspond to a buffer amplifier. The source follower transistor SF may be referred to as a source follower transistor. A gate of the source follower transistor SF is connected to the floating diffusion region FD. The source follower transistor SF may amplify a gate voltage value varied based on charges transferred to the floating diffusion region FD to output a pixel signal V_{OUT}.

A drain electrode of the selection transistor SEL may be connected to a source electrode of the source follower transistor SF, and the pixel signal Vout may be output through an output node in response to a selection signal SS.

Although FIG. 2 illustrates that one photoelectric conversion region and a unit pixel including four transistors TX, RX, SF, and SEL, the image sensor according to the present disclosure is not limited thereto. For example, the reset transistor RX, the source follower transistor SF, or the selection transistor SEL may be shared between adjacent pixels. Accordingly, the integration degree of the image sensor may be improved.

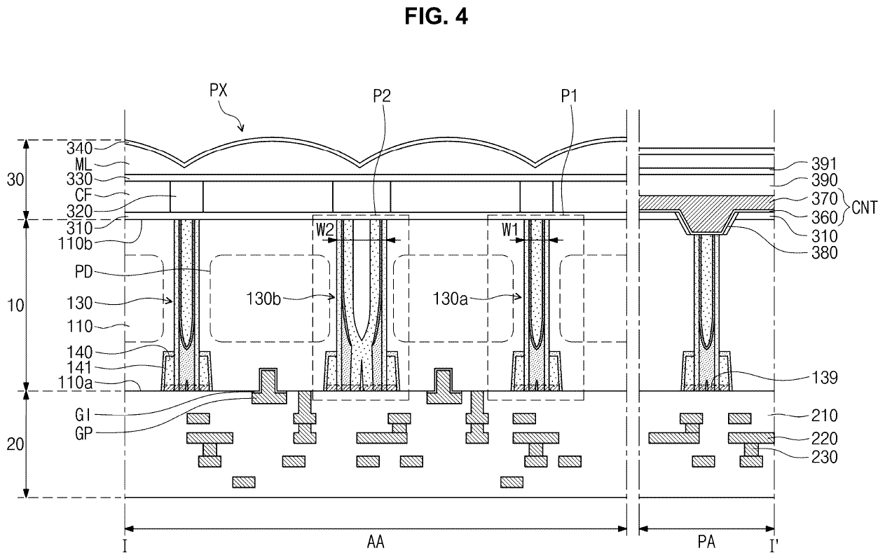

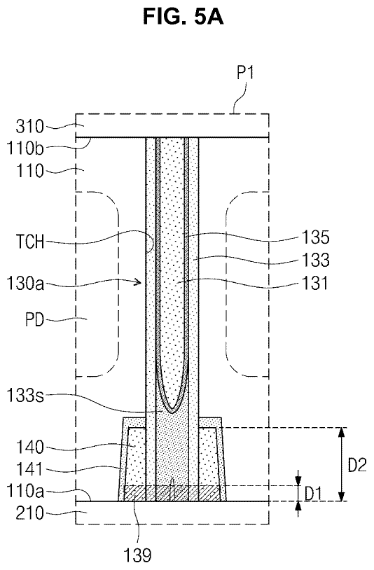

FIG. 3 is a plan view of an image sensor according to some example embodiments of the present disclosure. FIG. 4 is a cross-sectional view corresponding to line I-I′ of FIG. 3.

Referring to FIGS. 3 and 4, the image sensor may include a photoelectric conversion layer 10, a circuit wiring layer 20, and a light transmitting layer 30. The photoelectric conversion layer 10 may be interposed between the circuit wiring layer 20 and the light transmitting layer 30.

The photoelectric conversion layer 10 includes a semiconductor substrate 110 having a first surface 110a and a second surface 110b facing each other, an isolation layer 130 formed through the semiconductor substrate 110, and a photoelectric conversion region PD provided in the semiconductor substrate 110. The photoelectric conversion region PD, which serves as a region corresponding to the photoelectric conversion element, employs reference numeral PD the same as that of the photoelectric conversion element.

The semiconductor substrate 110 may include an active region AA, and a peripheral region PA provided to be adjacent to the active region AA. The peripheral region PA may be provided at one side of the active region AA at least, or may surround the active region AA, when viewed in a plan view.

The active region AA of the semiconductor substrate 110 is a region for a pixel array formed by arranging the plurality of pixels PX. The semiconductor substrate 110 may be a silicon substrate, a germanium substrate, a silicon-germanium substrate, a group II-VI compound semiconductor substrate 110, a group III-V compound semiconductor substrate 110, or a silicon on insulator (SOI) substrate. The semiconductor substrate 110 may include a first conductive type impurity. Accordingly, the semiconductor substrate 110 may have the first conductive type. The impurity of the first conductive type may be a group III element. For example, the impurities of the first conductive type may include aluminum (Al), boron (B), indium (In), and/or gallium (Ga).

The plurality of pixels PX may be arranged, in the form of a matrix, on the semiconductor substrate 110.

The isolation layer 130 may be interposed between the pixels PX. The pixels PX may be defined by the isolation layer 130. The isolation layer 130 is formed in the semiconductor substrate 110 in a direction perpendicular to the first surface 110a. The isolation layer 130 may be formed through, for example, the first surface 110a and the second surface 110b. The isolation layer 130 may extend from the first surface 110a to the second surface 110b. The first surface 110a may expose a bottom surface of the isolation layer 130, and may be coplanar with the bottom surface of the isolation layer 130. The second surface 110b may expose a top surface of the isolation layer 130, and may be coplanar with the top surface of the isolation layer 130.

According to the present disclosure, an upper portion, a lower portion, a top surface, a bottom surface, a direction facing the upper portion, or a direction facing the lower portion will be described based on the ground surface unless specified otherwise.

The isolation layer 130 includes side parts extending in the row direction and the column direction, and a crossing part provided at a crossing region where the side parts cross each other. The side parts correspond to sides of two adjacent pixels PX facing each other, and the crossing parts correspond to corners allowing four adjacent pixels PX to face each other.

According to some example embodiments of the present disclosure, an etching barrier layer 139 is provided in the isolation layer 130 to limit and/or prevent defects from being caused due to the loss of materials constituting the isolation layer 130 during the process of fabricating the image sensor. The details thereof will be described later.

The photoelectric conversion region PD may be disposed in each of the pixels PX. The photoelectric conversion region PD may be interposed between the first surface 110a and the second surface 110b of the semiconductor substrate 110. The photoelectric conversion regions PD may be a region doped with impurities of the second conductive type opposite to the first conductive type. According to some example embodiments of the present disclosure, the photoelectric conversion regions PD may include a group V element serving as an impurity, and the group V element may be an impurity in the second conductive type. The impurity of the second conductive type may include N-type impurities such as phosphorus, arsenic, bismuth, and/or antimony. The photoelectric conversion region PD may form a PN junction with the semiconductor substrate 110 to constitute a photodiode.

A shallow isolation layer 140 may be provided in each pixel PX. The shallow isolation layer 140 may be provided to be adjacent to the first surface 110a, and may be buried in the semiconductor substrate 110 from the first surface 110a. The shallow isolation layer 140 may be provided at an upper portion of the isolation layer 130.

A pad layer 141 may be provided between the shallow isolation layer 140 and the semiconductor substrate 110. The top surface of the shallow isolation layer 140 may be exposed by the first surface 110a. The shallow isolation layer 140 may include various insulating materials. For example, the shallow isolation layer 140 may include at least one of a silicon oxide layer, a silicon nitride layer, and a silicon oxynitride layer.

The circuit wiring layer 20 may be provided on the first surface 110a of the semiconductor substrate 110. The circuit wiring layer 20 may include a circuit unit including a gate pattern GP and a gate insulating layer GI, and contact vias 230 and conductive lines 220 connected to the circuit unit. The contact vias 230 and the conductive lines 220 may be provided in an interlayer insulating layer 210 stacked on the first surface 110a. The interlayer insulating layer 210 may cover the first surface 110a, the top surface of the isolation layer 130, and the top surface of the shallow isolation layer 140. The interlayer insulating layer 210 may cover transistors constituting the circuit unit. The conductive lines 220 may be electrically connected to transistors through the contact vias 230. The interlayer insulating layer 210 may include an insulating material, and the contact vias 230 and the conductive lines 220 may include a conductive material.

The gate pattern GP may be provided on the first surface 110a of the semiconductor substrate 110. The gate pattern GP may function as a gate electrode of each of the transfer transistor, the source follower transistor, the reset transistor, or the selection transistor to drive the image sensor. For example, the gate pattern GP may include a transfer gate, a source follower gate, a reset gate, or a selection gate. Alternatively, the gate pattern GP may include only a gate of the transfer transistor. When the gate pattern GP may include only a gate of the transfer transistor, the gates of remaining transistors may be formed on a substrate other than the semiconductor substrate 110 having the transfer transistor. For example, the image sensor may further include an additional substrate stacked on the semiconductor substrate 110. The source follower transistor, the reset transistor, or the selection transistor may be provided on the additional substrate.

Although the drawings illustrate that one gate pattern GP is disposed in each pixel PX for the illustrative purpose, the present disclosure is not limited thereto. A plurality of gate patterns GP may be disposed in each pixel PX. Although the gate pattern GP has a buried-type gate structure as illustrated in drawing, the present disclosure is not limited thereto. Alternatively, the gate pattern GP may have a planar-type structure. The gate pattern GP may include a metal material, a metal silicide material, a polysilicon, and the combination thereof.

The gate insulating layer GI may be interposed between the gate pattern GP and the semiconductor substrate 110. The gate insulating layer GI may include, for example, a silicon-based insulating material (e.g., silicon oxide, silicon nitride, and/or silicon oxynitride) and/or a high dielectric material (e.g., hafnium oxide and/or aluminum oxide).

The light transmitting layer 30 may be provided on the second surface 110b of the semiconductor substrate 110. The light transmitting layer 30, which is a layer to transmit light traveling from the outside to the photoelectric conversion region PD, and the second surface 110b of the semiconductor substrate 110 becomes an incident surface on which light is incident. The light transmitting layer 30 may include color filters CF provided on the second surface 110b, a fence pattern 320, and micro-lenses ML. The color filters CF may be interposed between the second surface 110b and the micro-lenses ML. The light transmitting layer 30 may condense and filter light incident from the outside, and may provide the light to the photoelectric conversion layer 10.

The color filters CF may be disposed on the pixels PX, respectively. According to some example embodiments, four pixels PX arranged in 2×2 may express the same color. Alternatively, each of four pixels PX arranged in 2×2 may express any one color of red, green and blue. For example, the four pixels PX may express red, green, green, and blue, sequentially.

The color filters CF may be disposed on the second surface 110b of the semiconductor substrate 110 for each pixel PX. For example, the color filters CF may be provided to positions corresponding to the photoelectric conversion region PD, respectively. Each of the color filters CF may be selected as one of the plurality of reference colors. The plurality of reference colors may be red, green, and blue (RGB), red, green, blue, and white (RGBW), cyan, magenta, and yellow (CMY), cyan, magenta, yellow, and black (CMYK), red, yellow, and blue (RYB), or an infrared ray (RGBIR) by way of example. However, the color of the color filters CF is not limited thereto. The filter having another color may be provided. The color filters CF may form color filter arrays.

The fence pattern 320 may be provided on the isolation layer 130. For example, the fence pattern 320 may be perpendicularly overlapped with the isolation layer 130. The fence pattern 320 may have the planar shape corresponding to the isolation layer 130. For example, when viewed in a plan view, the fence pattern 320 may have the form of a grid. When viewed in a plan view, the fence pattern 320 may surround the color filters CF. At least a portion of the fence pattern 320 may be perpendicularly (for example, a third direction D3) overlapped with the isolation layer 130.

The fence pattern 320 may be interposed between two adjacent filters CF. The plurality of color filters CF may be separated from each other physically and optically by the fence pattern 320. Accordingly, the fence pattern 320 may guide light incident onto the second surface 110b, into the photoelectric conversion region PD.

The fence pattern 320 may include metal, but the present disclosure is not limited thereto. The fence pattern 320 may include a low refractive index material. The low refractive index material may include a polymer and silica nanoparticles in the polymer. The low refractive index material may have an insulating property. For another example, the fence pattern 320 may include metal and/or metal nitride. For example, the fence pattern 320 may include titanium and/or titanium nitride.

The micro-lenses ML may be disposed on the plurality of color filters CF. At least a portion of the micro-lenses ML may be perpendicularly (for example, the third direction D3) overlapped with the photoelectric conversion region PD. The micro-lenses ML, which are to condense light incident toward the semiconductor substrate 110, may be a spherical lens, an aspherical lens, or the combination thereof. The micro-lenses ML may be provided at positions corresponding to the photoelectric conversion regions PD of the semiconductor substrate 110.

The micro-lens ML may be transparent and transmit light. The micro-lens ML may include an organic material such as a polymer. For example, the micro-lens ML may include a photoresist material or a thermosetting resin.

According to some example embodiments of the present disclosure, the color filters CF, the fence patterns 320, and/or the micro-lenses ML are provided by overlapping positions corresponding to pixels PX, but the present disclosure is not limited thereto. At least one of the color filters CF, the fence patterns 320, and the micro-lenses ML may have an offset structure shifted by a specific degree at a position corresponding to each pixel PX. The offset structure may be formed due to the process margin of the color filters CF, the fence patterns 320, and/or the micro-lenses ML, or may be intentionally selected to optimize the optical path by considering the angle of light traveling from the outside to the pixel PX.

A passivation layer 340 may be provided on the micro-lenses ML. The micro-lenses ML and the passivation layer 340 may extend to the peripheral region PA, in a flat shape on the second surface 110b.

An upper insulating layer 310 may be interposed between the second surface 110b of the semiconductor substrate 110 and the color filters CF, and interposed between the isolation layer 130 and the fence pattern 320. The upper insulating layer 310 may cover the second surface 110b of the semiconductor substrate 110 and the top surface of the isolation layer 130. The upper insulating layer 310 may include a plurality of layers. For example, the upper insulating layer 310 may include an antireflective layer. The antireflective layer may include various materials. For example, the antireflective layer may include a hafnium oxide (HfOx), a zirconium oxide (ZrO₂), a titanium oxide (TiO₂), an aluminum oxide (Al₂O₃, alumina), a silicon oxide (SiO₂), a tantalum oxide (Ta₂O₃), or plasma enhanced-tetra ethylene orthosilicate (PE-TEOS). In some example embodiments, the upper insulating layer 310 may prevent light from being reflected, such that light incident to the second surface 110b of the semiconductor substrate 110 may smoothly reach the photoelectric conversion region PD.

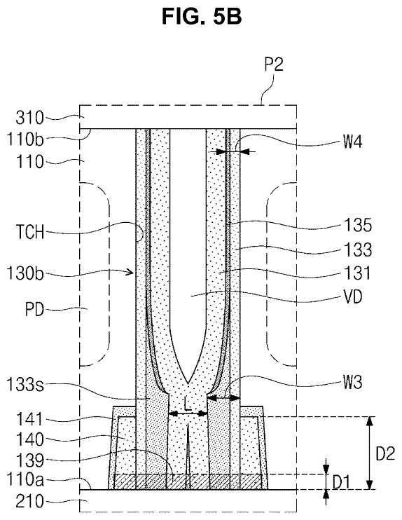

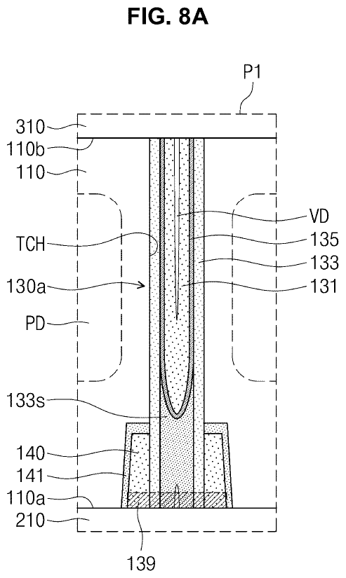

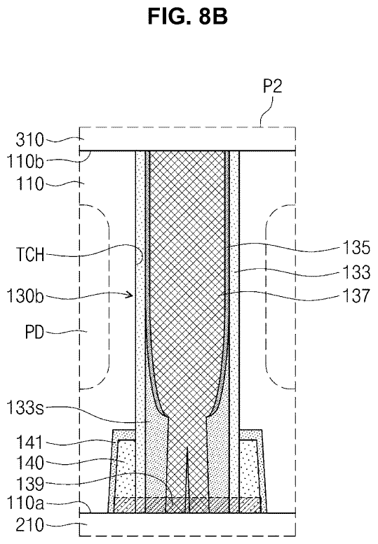

A contact part CNT may be provided in the peripheral region PA of the semiconductor substrate 110. The contact part CNT may be disposed adjacent to the second surface 110b, and may be partially buried in the semiconductor substrate 110. The contact part CNT may directly make contact with a top surface of a buried conductive pattern 137 and/or of a conductive liner 135 to be described below (e.g., see FIGS. 5A and 8B).

The contact part CNT may include a metal pattern 370 extending from the upper insulating layer 310 into the semiconductor substrate 110 and a barrier pattern 360 surrounding the metal pattern 370.

A contact insulating layer 380 may be provided on an outer portion of the contact part CNT to surround the contact part CNT. Although not illustrated, the contact part CNT may extend to another region to be electrically connected to a through silicon via (TSV) or a back vias stack (BVS). Accordingly, the negative bias voltage may be applied to the conductive liner 135 through the contact part CNT. Accordingly, a white spot or dark current problem may be limited and/or prevented or reduced.

According to some example embodiments of the present disclosure, the contact part CNT may be provided on the second surface 110b as illustrated in FIG. 4, but the present disclosure is not limited thereto. According to some example embodiments of the present disclosure, the contact part CNT may be provided on the first surface 110a. Accordingly, the negative bias voltage may be applied to the buried conductive pattern 137 and/or the conductive liner 135 through the contact part CNT. According to some example embodiments, a wiring connected to the conductive liner 135 may be additionally provided in the circuit wiring layer 20 on the bottom surface of the isolation layer 130.

A bulk color filter 390 and a protective layer 391 may be sequentially provided on the contact part CNT in the peripheral region PA. The bulk color filter 390 may be interposed between the contact part CNT and the micro-lenses ML, and the protective layer 391 may be interposed between the bulk color filter 390 and the micro-lenses ML.

Hereinafter, the isolation layer according to some example embodiments of the present disclosure will be described in detail.

FIGS. 5A and 5B are cross-sectional views illustrating parts P1 and P2 of FIG. 4. FIG. 5A illustrates an isolation layer of a side part, and FIG. 5B illustrates an isolation layer of a crossing part.

Referring to FIGS. 3, 4, 5A, and 5B, the pixels PX are arranged in the form of a matrix, when viewed in a plan view, and divided by the isolation layer 130.

The isolation layer 130 includes a first isolation layer 130a provided at the side part extending in the row direction and the column direction, and a second isolation layer 130b provided at the crossing part at which the side parts cross each other.

According to some example embodiments of the present disclosure, the isolation layer 130 may include an insulating material and a conductive material. The isolation layer 130 may include an insulating liner 133, the conductive liner 135, a buried insulating pattern 131, a support 133s, and the etching barrier layer 139, and the insulating liner 133, the buried insulating pattern 131, the support 133s, and the etching barrier layer 139 include an insulating material.

The isolation layer 130 may have mutually different widths depending on the arrangement form and the positions of the pixels PX. For example, the width of the first isolation layer 130a at the side part may be different from the width of the second isolation layer 130b at the crossing part. On the assumption that the width of the first isolation layer 130a and the width of the second isolation layer 130b are a first width W1 and a second width W2, respectively, the second width W2 may be greater than the first width W1.

According to some example embodiments of the present disclosure, the isolation layer 130 may have a width and a shape varying depending on the region for the isolation layer 130. The shape of the isolation layer 130, which vary depending on the region, may depend on the fabricating processes. For example, the first isolation layer 130a and the second isolation layer 130b may have at least a portion different from a remaining portion.

First, referring to FIG. 5A, regarding the first isolation layer 130a, the first isolation layer 130a may be provided in a trench TCH formed through the first surface 110a and the second surface 110b of the semiconductor substrate 110, and may include the insulating liner 133, the conductive liner 135, and the buried insulating pattern 131 sequentially arranged in a direction away from the photoelectric conversion region PD. In some example embodiments, the semiconductor substrate 110 may be characterized as defining the trench TCH therein from the first surface 110a to the second surface 110b. The first isolation layer 130a may include the support 133s which is adjacent to the first surface 110a and interposed between the insulating liner 133 and the conductive liner 135, and the etching barrier layer 139 provided to have a specific depth from the first surface 110a.

The insulating liner 133 may be provided along the sidewall of the trench TCH. The insulating liner 133 may cover the second surface 110b of the semiconductor substrate 110 and the sidewall of the trench TCH formed through the second surface 110b of the semiconductor substrate 110. The insulating liner 133 may extend from the first surface 110a to the second surface 110b. The bottom surface and the top surface of the insulating liner 133 may be coplanar with the first surface 110a and the second surface 110b, respectively. Hereinafter, surfaces coplanar with the first surface 110a are referred to as the first surface 110a, for the illustrative purpose, and surfaces coplanar with the second surface 110b are referred to as the second surface 110b.

The insulating liner 133 is interposed between the conductive liner 135 and the semiconductor substrate 110, to electrically isolate the semiconductor substrate 110 from the conductive liner 135. The insulating liner 133 may surround the pixel PX and may be positioned inside the conductive liner 135, when viewed in a plan view.

The insulating liner 133 may include an insulating material, for example, a silicon-based insulating material (Si₃N₄), silicon oxide (SiO₂; silicate), silicon carbon nitride (SiCN), silicon oxygen carbon nitride (SiOCN), and the like, or may include a high-k metal oxide (e.g., hafnium oxide (HfOx), zirconium oxide (ZrO₂), titanium oxide (TiO₂), aluminum oxide (Al₂O₃; alumina), The insulating liner 133 may include a material having a refractive index lower than of the semiconductor substrate 110.

Although the insulating liner 133 includes one layer according to some example embodiments of the present disclosure, the present disclosure is not limited thereto. For another example, the insulating liner 133 may include a plurality of layers, and the layers may include mutually different materials. For example, the insulating liner 133 may include a complex layer including a silicon oxide and a silicon nitride (e.g., SiN, SiCN, or SiOCN).

The support 133s is provided in the trench TCH having the insulating liner 133. The support 133s is provided at a side, which is close to the first surface 110a, in the space of the trench TCH.

The support 133s is provided to have a specific depth from the first surface 110a to the second surface 110a. A depth of the support 133s may be equal to or similar to a depth of the shallow isolation layer 140. A bottom surface of the support 133s may be coplanar with the first surface 110a. A cavity which is not filled with a material forming the support 133s may be formed in the bottom surface of the support 133s. The cavity may have a seam shape. The support 133s may have a concave-up shape. The top surface of the support 133s may have a tapered shape, such as a V shape or a U shape, increasing in height outward from the central portion of the support 133s.

The conductive liner 135 is interposed between the insulating liner 133 and the buried insulating pattern 131. The conductive liner 135 surrounds the circumference of each pixel PX, when viewed in a plan view. The conductive liner 135 makes contact with the top surface of the support 133s and the sidewalls of the insulating liner 133 while covering the top surface of the support 133s and the sidewalls of the insulating liner 133.

The conductive liner 135 may extend from the second surface 110b toward the first surface 110a when viewed in a cross-sectional view. The top surface of the conductive liner 135 may be coplanar with the second surface 110b. The conductive liner 135 may be provided to have a specific length from the second surface 110b toward the first surface 110a. The specific length may be smaller than the distance between the first surface 110a and the second surface 110b, that is, the thickness of the semiconductor substrate 110. According to some example embodiments of the present disclosure, the length of the conductive liner 135 may be smaller than the distance between the first surface 110a and the second surface 110b as illustrated in drawings.

The conductive liners 135 surround the peripheral portions of the pixels PX and are connected to each other between two adjacent pixels PX. The conductive liner 135 may cover a top surface of the support 133s, which has a concave shape, and may have a structure blocked in bottom surface, that is, toward the first surface 110a inside the trench TCH. As the conductive liners 135 surrounding the pixels PX adjacent to each other are connected to each other, the conductive liners 135 may receive electrically equal voltages, for example, negative bias voltages. When the negative bias voltage is applied to the conductive liner 135, holes may be stably collected in the vicinity of the conductive liner 135 in a region adjacent to the isolation layer 130.

The conductive liner 135 may include a conductive material, for example, impurity-doped silicon, metal, or a metal oxide. The impurity-doped silicon may be polysilicon doped with impurities of the first conductive type or second conductive type. For example, the conductive liner 135 may include polycrystalline silicon doped with boron (B). Alternatively, the conductive liner 135 may include polycrystalline silicon doped with phosphorus (P) or arsenic (As). When boron or phosphorus is doped as an impurity, the concentration of the impurity may be about 5.0×10¹⁹ to about 5.0×10²²/cm³. According to some example embodiments of the present disclosure, the impurity doped in the conductive liner 135 may be diffused in the form of the buried conductive pattern 137 through annealing treatment in the fabricating process. In some example embodiments, the electric conductivity of the buried conductive pattern 137 may be increased. As the electric conductivity of the buried conductive pattern 137 is improved, the efficiency of applying the negative bias to the isolation layer 130 is improved. Accordingly, the sensitivity of the image device is improved.

When the conductive liner 135 includes a metal, the metal may include tungsten, or aluminum. The material constituting the conductive liner 135 is not limited thereto. For example, the material may include another material having conductivity, for example, various metal other than the metal, such as tungsten or aluminum, a conductive material including the various metal, or an inorganic material doped with the various metal.

The buried insulating pattern 131 is filled in the trench TCH having the conductive liner 135. The buried insulating pattern 131 may extend from the second surface 110b toward the first surface 110a, and may be filled in the trench TCH to have a specific depth from the first surface 110a. A bottom surface of the support 133s may be coplanar with the first surface 110a.

The buried insulating pattern 131 may be formed of an insulating material having excellent gap fill characteristics. For example, the buried insulating pattern 131 may include a boron-phosphorus silicate glass (BPSG) film, a high density plasma (HDP) oxide film, a fluid chemical vapor deposition (FCVD), a tetraethyl orthosilicate (O₃-TEOS) film, an undoped silicate glass (USG) or a Tonen SilaZene (TOSZ) material. However, the buried insulating pattern 131 is not limited thereto. For example, the buried insulating pattern 131 may include a silicon nitride and/or a silicon oxynitrde, and an oxide film including silicon oxide.

According to some example embodiments of the present disclosure, the buried insulating pattern 131 may include one selected from among materials having relatively low light absorption. For example, the buried insulating pattern 131 may include a material having lower light absorption rate than doped silicon or undoped silicon.

The etching barrier layer 139 limits and/or prevents the insulating material of the isolation layer 130 from being lost, when the image sensor is fabricated. The etching barrier layer 139 is provided at a lower region of the isolation layer 130. The etching barrier layer 139 may be provided to have a specific depth from the first surface 110a of the isolation layer 130.

The etching barrier layer 139 may be a portion of the support 133s, the insulating liner 133, and the shallow isolation layer 140 and is a region doped with a specific impurity. According to some example embodiments of the present disclosure, the etching barrier layer 139 is formed with a specific thickness depending on the extent of the doping into the support 133s, the insulating liner 133, and the shallow isolation layer 140. The support 133s, the insulating liner 133, and the shallow isolation layer 140 forming the etching barrier layer 139 are parts including the insulating material. The etching barrier layer 139 is a region doped with an insulating material in the form of specific impurities. The etching barrier layer 139 has higher corrosion resistance than other regions of the semiconductor substrate that is not doped with impurities.

Various kinds of impurities may be used as the impurities. For example, the impurities may include B, C, N, Ar, He, Si, As, P, BF_{2/3}, or Sb. The impurities may be doped into the isolation layer 130 at a concentration of about 1.0×10¹⁴/cm² to about 2.0×10¹⁶/cm².

As the etching barrier layer 139 is doped with impurities, the etching barrier layer 139 has higher corrosion resistance than another component constituting the first surface 110a. For example, the etching barrier layer 139 has a smaller etch rate and/or etch amount with respect to a specific etchant. For example, the etching barrier layer 139 has a smaller etch rate than that of the semiconductor substrate 110 having the first surface 110a with respect to the specific etchant.

According to some example embodiments of the present disclosure, on the assumption that the thickness of the etching barrier layer 139, that is, the depth from the first surface 110a is a first depth D1, the first depth D1 may be in the range of about 1 Å to about 1800 Å, or the range of about 50 Å to about 1500 Å. The etching barrier layer 139 may have the thickness thinner than that of the isolation layer 140 which is shallow. On the assumption that the depth of the shallow isolation layer 140 from the first surface 110a is a second depth D2, the first depth D1 may have the value in the range of about 1% to about 80% of the second depth D2, or the range of about 5% to 70%.

Next, regarding the second isolation layer 130b to be described with reference to FIG. 5B, although the second isolation layer 130b has a shape similar to that of the first isolation layer 130a, the second isolation layer 130b has a difference from the first isolation layer 130a in the shape of the support 133s and the shape of the buried insulating pattern 131, at a part, which is close to the first surface 110a of the semiconductor substrate 110.

The second isolation layer 130b may be provided in the trench TCH formed through the first surface 110a and the second surface 110b of the semiconductor substrate 110, and may include the insulating liner 133, the conductive liner 135, and the buried insulating pattern 131 sequentially provided in a direction away from the photoelectric conversion region PD. The second isolation layer 130b may include the support 133s adjacent to the first surface 110a and interposed between the insulating liner 133 and the conductive liner 135, and the etching barrier layer 139 provided to have a specific depth from the first surface 110a.

The insulating liner 133 may be provided along the sidewall of the trench TCH. The insulating liner 133 may cover the second surface 110b of the semiconductor substrate 110 and the side wall of the trench TCH formed through the second surface 110b of the semiconductor substrate 110. The insulating liner 133 may extend from the first surface 110a to the second surface 110b. The bottom surface and the top surface of the insulating liner 133 may be coplanar with the first surface 110a and the second surface 110b.

The support 133s is provided inside the trench having the insulating liner 133 to cover a portion of inner sidewalls of the trench TCH having the insulating liner 133. The support 133s is provided at a side, which is close to the first surface 110a, in an inner space of the trench TCH. The support 133s is provided to have a specific depth from the first surface 110a to the second surface 110b. The depth of the support 133s may be equal to or different from the depth of the support 133s inside the second isolation layer 130b. According to some example embodiments of the present disclosure, the depth of the support 133s may be substantially equal to the depth of the shallow isolation layer 140. A bottom surface of the support 133s may be coplanar with the first surface 110a. The top surface of the support 133s may have a tapered shape, such as a V shape or a U shape, increasing in height outward from the central portion of the support 133s.

According to some example embodiments of the present disclosure, the support 133s may be provided only on the sidewall, instead of being provided at the central portion of the trench TCH. For example, supports 133s may surround peripheral portions of the pixels PX inside the second isolation layer 130b and may be spaced apart from each other by a specific distance L between two adjacent pixels PX.

The conductive liner 135 is interposed between the semiconductor substrate 110 and the buried insulating pattern 131. The conductive liner 135 may cover the top surface of the support 133s and the sidewalls of the insulating liner 133. The covering range of the conductive liner 135 for the top surface of the support 133s may vary depending on the width of the trench TCH. When the width of the trench TCH is two times greater than the thickness of the conductive liner 135, the conductive liner 135 may not be provided in a lower portion of the support 133s, but may be provided only on the support 133s having the tapered shape. Accordingly, the conductive liners 135 disposed on opposite sidewalls of the trench TCH may be spaced apart from each other while surrounding two adjacent pixels.

The conductive liner 135 may extend from the second surface 110b to the first surface 110a when viewed in a cross-sectional view. The top surface of the conductive liner 135 may be coplanar with the second surface 110b. The conductive liner 135 may be provided by a specific length from the second surface 110b towards the first surface 110a. The specific length may be smaller than the distance between the first surface 110a and the second surface 110b, that is, the thickness of the semiconductor substrate 110. According to some example embodiments of the present disclosure, the length of the conductive liner 135 may be smaller than the distance between the first surface 110a and the second surface 110b as illustrated in drawings.

The buried insulating pattern 131 is filled by the specific thickness in the trench TCH having the conductive liner 135 and the support 133s.

The buried insulating pattern 131 may extend from the second surface 110b toward the first surface 110a. The buried insulating pattern 131 may be formed from the first surface 110a to the second surface 110b, and may be filled in the trench TCH. The top surface of the buried insulating pattern 131 may be coplanar with the second surface 110b, and the bottom surface of the buried insulating pattern 131 may be coplanar with the first surface 110a.

The buried insulating pattern 131 covers the inner sidewall of the trench TCH in the conductive liner 135 and the support 133s with a specific thickness. In some example embodiments, the buried insulating pattern 131 may be provided only on the opposite sidewalls of the trench TCH corresponding to the conductive liner 135, and a cavity VD may be formed without the buried insulating pattern 131, in an intermediate part (that is, the central part) between the opposite sidewalls. Accordingly, the buried insulating pattern 131 may have a concave-up shape. For example, the top surface of the buried insulating pattern 131 may have a tapered shape, such as a V shape or a U shape, increasing in height outward from the central portion of the trench TCH.

The cavity VD formed by the buried insulating pattern 131 may be filled with at least one of air or an insulating material. The buried insulating pattern 131 may be characterized as defining cavity VD therein, and cavity VD may be empty, filled with air, or filled with insulating material. When the insulating material is filled in the cavity VD, the insulating material may be filled in a portion or the entire portion of the cavity VD. The type of the insulating material is not particularly limited, but may include the same material as that of the upper insulating layer 310. For example, the insulating material may include hafnium oxide (HfOx), zirconium oxide (ZrO₂), titanium oxide (TiO₂), aluminum oxide (Al₂O₃; alumina), silicon oxide (SiO₂), tantalum oxide (Ta₂O₃), plasma enhanced-tetra ethylene orthosilicate (PE-TEOS), etc.

According to some example embodiments of the present disclosure, in the crossing part of the second isolation layer 130b, the width of an outer insulating material except the buried insulating pattern 131 may vary depending on positions. For example, in the second isolation layer 130b at the crossing part, an outer insulating material of a portion closer to the first surface 110a may have a width different from a width of an outer insulating material of a portion close to the second surface 110b. For example, the outer insulating material of the portion closer to the first surface 110a may have a larger width. According to some example embodiments of the present disclosure, the outer insulating material of the portion closer to the second surface 110b includes the insulating liner 133, and the outer insulating material of the portion close to the first surface 110a includes the insulating liner 133 and the support 133s. On the assumption that a width of the outer insulating material of the portion closer to the first surface 110a is a third width W3, and a width of the outer insulating material of the portion closer to the second surface 110b is a fourth width W4, the third width W3 may be larger than the fourth width W4.

According to some example embodiments of the present disclosure, the top surface of the buried insulating pattern 131 may have a tapered shape, for example, a V shape.

The etching barrier layer 139 limits and/or prevents the insulating layer of the isolation layer 130 from being lost when the image sensor is fabricated. The etching barrier layer 139 is provided in a lower region of the isolation layer 130. The etching barrier layer 139 may be provided to have a specific depth of the isolation layer 130 from the first surface 110a. The etching barrier layer 139 may be formed by doping impurities into the support 133s, the insulating liner 133, and the shallow isolation layer 140. According to some example embodiments of the present disclosure, the etching barrier layer 139 is formed with a specific thickness depending on the extent of the doping into the support 133s, the insulating liner 133, and the shallow isolation layer 140.

According to some example embodiments of the present disclosure, the first isolation layer 130a and the second isolation layer 130b may have various modifications in material and shape without deviating from the technical scope of the present disclosure. The following description will be described while focusing on the difference from the above embodiment for the illustrative purpose.

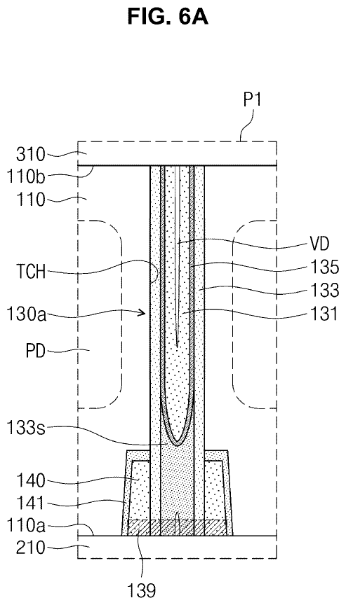

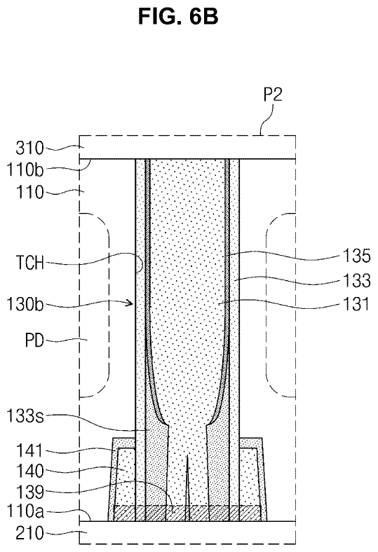

FIGS. 6A and 6B are cross-sectional views illustrating parts corresponding to parts P1 and P2, in the image sensor according to some example embodiments of the present disclosure. FIG. 6A illustrates a first isolation layer at a side part, and FIG. 6B illustrates a second isolation layer at a crossing part.

Referring to FIGS. 6A and 6B, the buried insulating pattern 131 may be filled in the trench TCH, which are formed in the first isolation layer 130a and the second isolation layer 130b, without the cavity VD. The concave shape of the top surface of the buried insulating pattern 131 is made due to the fabricating process. When the process condition is changed, the top surface of the buried insulating pattern 131 may have another shape. According to some example embodiments of the present disclosure, the buried insulating pattern 131 is provided inside the trench TCH having the insulating liner 133, the conductive liner 135, and the support 133s. The buried insulating pattern 131 may be filled in the entire portion of a remaining inner portion of the trench TCH except for the insulating liner 133, the conductive liner 135, and the support 133s.

The buried insulating pattern 131 may be formed of an insulating material having excellent gap fill characteristics. For example, the buried insulating pattern 131 may include a boron-phosphorus silicate glass (BPSG) film, a high density plasma (HDP) oxide film, a fluid chemical vapor deposition (FCVD), a tetraethyl orthosilicate (O₃₋TEOS) film, an undoped silicate glass (USG) or a Tonen SilaZene (TOSZ) material. However, the buried insulating pattern 131 is not limited thereto. For example, the buried insulating pattern 131 may include a silicon nitride and/or a silicon oxynitrde, and an oxide film including silicon oxide. For example, the insulating material may include a material the same as that of the upper insulating material, for example, hafnium oxide (HfOx), zirconium oxide (ZrO₂), titanium oxide (TiO₂), aluminum oxide (Al₂O₃, alumina), silicon oxide (SiO₂), tantalum oxide (Ta₂O₃), or plasma enhanced-tetra ethylene orthosilicate (PE-TEOS).

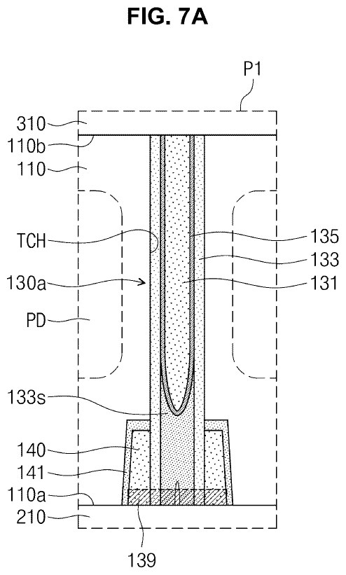

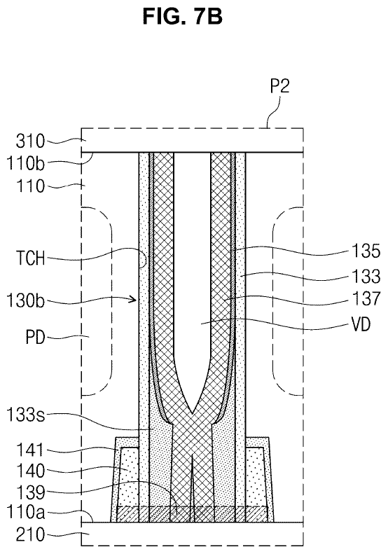

FIGS. 7A and 7B are cross-sectional views illustrating parts corresponding to parts P1 and P2, in the image sensor according to some example embodiments of the present disclosure. FIG. 7A illustrates a first isolation layer at a side part, and FIG. 7B illustrates a second isolation layer at a crossing part.

Referring to FIG. 7A, the first isolation layer 130a at the side part may be provided in substantially the same shape as that of some example embodiments described above. However, FIG. 7B illustrates that a cavity VD having a seam shape is formed inside the buried conductive pattern 137. The cavity VD of the buried conductive pattern 137 may be provided or not, depending on the width of the trench TCH.

Referring to FIG. 7B, the second isolation layer 130b at the crossing part has a difference from some example embodiments described above, in that the buried conductive pattern 137 is provided instead of the buried insulating pattern 131. For example, the buried conductive pattern 137 is provided and filled in the trench TCH.

According to some example embodiments, the buried conductive pattern 137 of the second isolation layer 130b may be provided in the shape similar to the shape of the buried insulating pattern 131 illustrated in FIG. 5B. For example, the buried conductive pattern 137 may have a top surface in a concave shape, and the cavity VD may be formed at the central portion of the trench TCH. The cavity VD may be filled with air or an insulating material.

The buried conductive pattern 137 may include a material including metal. Alternatively, the buried conductive pattern 137 may include polysilicon doped with impurities. The dopant of the polysilicon doped with impurities may include impurities of the first conductive type or in the second conductive type. For example, the buried conductive pattern 137 may include polycrystalline silicon doped with boron.

When the buried conductive pattern 137 includes a metal, copper, tungsten, aluminum, or titanium may be used, but the present disclosure is not limited thereto. For example, the buried conductive pattern 137 may include another material having conductivity, such as various metals, impurity-doped organic/inorganic materials, or the combination thereof. Another material having conductivity may include, for example, a conductive metal oxide, a metal grid, a random metal network, carbon nanotubes, graphene, a nanowire mesh, an ultra-thin metal film, or a conductive polymer. According to some example embodiments of the present disclosure, the conductive metal oxide may include indium tin oxide (ITO), indium zinc oxide (IZO), aluminum-doped zinc oxide (ZnO Al; AZO), indium gallium zinc oxide (IGZO), fluorine-doped tin oxide, or niobium-doped anatase. The buried conductive pattern 137 may be formed through thin film depositing, epitaxial growth, and impurity doping. For example, a conductive oxide and a metal such as indium tin oxide may be formed using a physical/chemical deposition process, and impurity-doped silicon may be formed through deposition or epitaxial growth (boron, phosphorus, arsenic doping).

According to some example embodiments of the present disclosure, the buried conductive pattern 137 may be provided only to the second isolation layer 130b at the crossing part. The side surface of the buried conductive pattern 137 may directly make contact with the conductive liner 135 of an adjacent pixel PX. Accordingly, the buried conductive patterns 137 serve as bridges to electrically connect adjacent pixels PX to each other. Accordingly, the conductive liners 135 are physically spaced apart from each other between the two adjacent pixels PX at the crossing part and electrically connected to each other through the buried conductive pattern 137. When the negative bias voltage is applied to the buried conductive pattern 137, the negative bias voltage is applied only to the conductive liner 135 without change. In contrast, when the negative bias voltage is applied to the conductive liner 135, the same voltage may be applied to the buried conductive pattern 137.

FIGS. 8A and 8B are cross-sectional views illustrating parts corresponding to parts P1 and P2 of FIG. 4, in the image sensor according to some example embodiments of the present disclosure. FIG. 8A illustrates a first isolation layer at a side part, and FIG. 8B illustrates a second isolation layer at a crossing part.

Referring to FIG. 8A, the first isolation layer 130a at the side part may be provided in substantially the same shape as that of some example embodiments described above. However, FIG. 8A illustrates that the cavity VD having the seam shape is formed inside the buried insulating pattern 131. The cavity VD of the buried insulating pattern 131 may be provided or not depending on the width of the trench TCH.

Referring to FIG. 8B, the second isolation layer 130b at the crossing part has a difference from some example embodiments described above in that the buried conductive pattern 137 is provided instead of the buried insulating pattern 131. For example, the buried conductive pattern 137 is provided and filled in the trench TCH. According to the some example embodiments, the buried conductive pattern 137 of the second isolation layer 130b may be provided in the shape similar to the shape of the buried insulating pattern 131 illustrated in FIG. 6B. For example, the buried conductive pattern 137 having no cavity VD may be filled in the trench TCH inside the second isolation layer 130b.

As illustrated in FIGS. 7A, 7B, 8A, and 8B, according to some example embodiments of the present disclosure, the buried conductive pattern 137, which may absorb light, may be provided to the crossing part. The buried conductive pattern 137 provided to the crossing part may reflect light, which travels toward the crossing part, to the photoelectric conversion region PD. In particular, when the buried conductive pattern 137 is formed of a metal material, the light traveling toward the crossing part, due to the light reflection effect due to the metal material, may be reflected into the pixel PX. The optical path of the light traveling toward the crossing part may be changed by the buried conductive pattern 137. Accordingly, the light efficiency of the image sensor and the sensitivity of the image sensor may be improved.

Even when the buried conductive pattern 137 includes polysilicon, the light traveling toward the crossing part travels toward edges of the pixels PX adjacent to each other. Accordingly, even when the light is absorbed by the buried conductive pattern 137, the light is not exerted on the influence of the photoelectric conversion efficiency of the photoelectric conversion region PD. Accordingly, the cross-talk resulting from the light traveling to another pixel PX through the edges of the pixels PX adjacent to each other may be limited and/or prevented.

In the image sensor having the above-described structure, defects caused by the dark current may be reduced (and/or minimized) while the loss of the incident light is reduced (and/or minimized).

In the image sensor, the main cause of the dark level is a dark current. The dark current is generated due to the accumulation of electrons generated from the interface between the isolation layer 130 and the photoelectric conversion region PD. To improve against defects caused by the dark current, the electrons generated from the interface between the isolation layer 130 and the photoelectric conversion region PD have to be captured. Accordingly, the electrons are limited and/or prevented from moving to the photoelectric conversion region PD. To this end, according to conventional approaches, the polysilicon is filled in the trench (TCH), such that the conductive isolation layer is formed. As the negative bias voltage is applied to the conductive isolation layer to limit and/or prevent a dark current.

However, when polysilicon is filled in a trench (TCH) and used for a conductive isolation layer, the polysilicon conductive isolation layer may absorb incident light. The polysilicon has a light absorption rate higher than that of the insulating material, such as a silicon oxide, or air. Accordingly, the light traveling to the photoelectric conversion region PD of the image sensor is reduced, thereby reducing the sensitivity of the image sensor.

According to the present disclosure, the negative bias is identically applied to the isolation layer 130, and the absolute volume of polysilicon used for the isolation layer 130 is reduced, thereby limiting and/or preventing the absorption of light traveling into each pixel PX at the maximum. To this end, according to some example embodiments of the present disclosure, polysilicon greatly absorbing light is not filled in the trench TCH. The buried insulating pattern 131 is formed using a material having light absorption rate lower than that of the polysilicon, thereby reducing (and/or minimizing) the light absorption into the polysilicon. The conductive liner 135 having a lesser thickness is formed between the buried insulating pattern 131 and the insulating liner 133. The conductive liner 135 interposed between the insulating liner 133 and the buried insulating pattern 131 has a thickness less than a conductive liner including existing polysilicon filled in the trench TCH. Even if a material having a higher absorption rate, such as polysilicon, is used, the light absorption rate is significantly reduced compared to existing polysilicon.

Since the conductive liner 135 has conductivity, a negative bias voltage is applied to the isolation layer 130 through the conductive liner 135. Accordingly, the effect of limiting and/or preventing the dark current by existing polysilicon may be sufficiently obtained through the conductive liner 135.

According to some example embodiments of the present disclosure, the etching barrier layer 139 is provided in the image sensor, thereby reducing (and/or minimizing) the device defect in the process for fabricating the image sensor. In the image sensor, the isolation layer 130 is formed through various processes using various insulating materials. The insulating layer is unintentionally etched in the process of forming the isolation layer 130, thereby causing the defect. The etching barrier layer 139 minimizes unintentional etching of the insulating layer. Accordingly, defects of the isolation layer 130 may be reduced (and/or minimized). The details thereof will be described later.

Accordingly, the negative bias is applied to the conductive liner 135 to limit and/or prevent the image sensor from being defective due to the dark current, and reducing (and/or minimizing) the light absorption rate by the existing polysilicon. The buried insulating pattern 131 having the higher light transmittance is used to reduce (and/or minimize) the loss of light incident to the photoelectric conversion region PD. Accordingly, the loss of light incident into the photoelectric conversion region PD is reduced (and/or minimized) to improve the photoelectric conversion efficiency and improve the sensitivity of the image sensor.

The image sensor having the above-described structure may be fabricated through the subsequent processes. Accordingly, hereinafter, the image sensor will be described with reference to accompanying drawing.

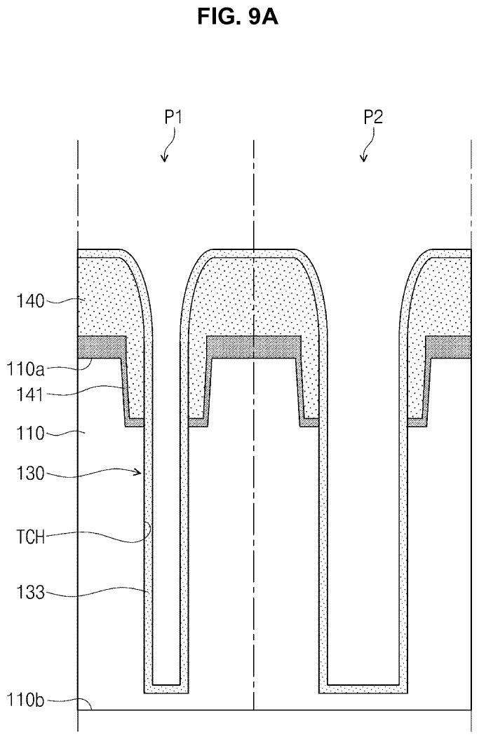

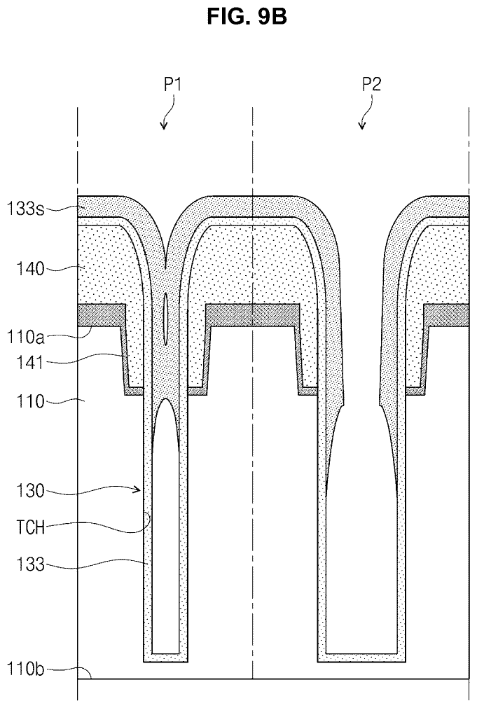

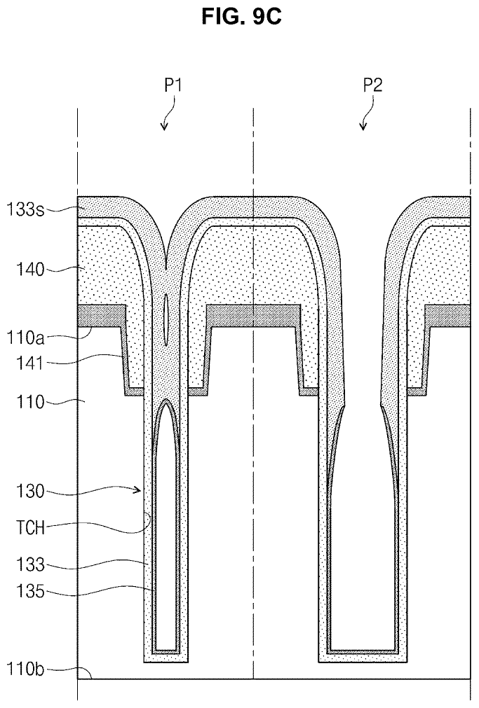

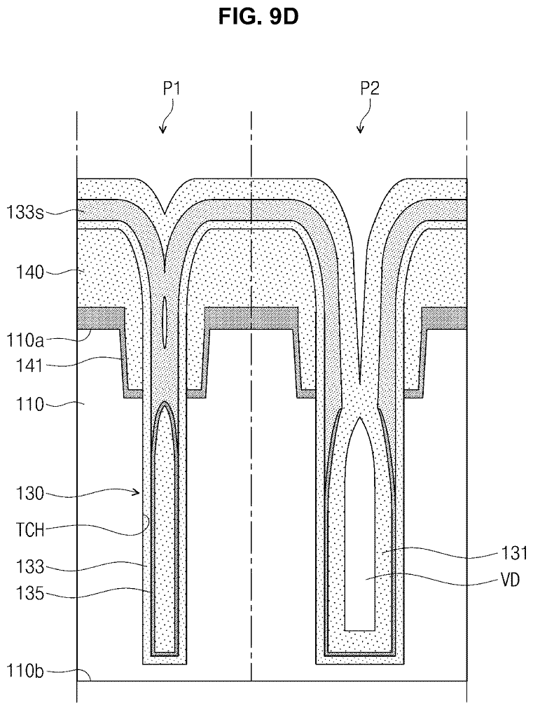

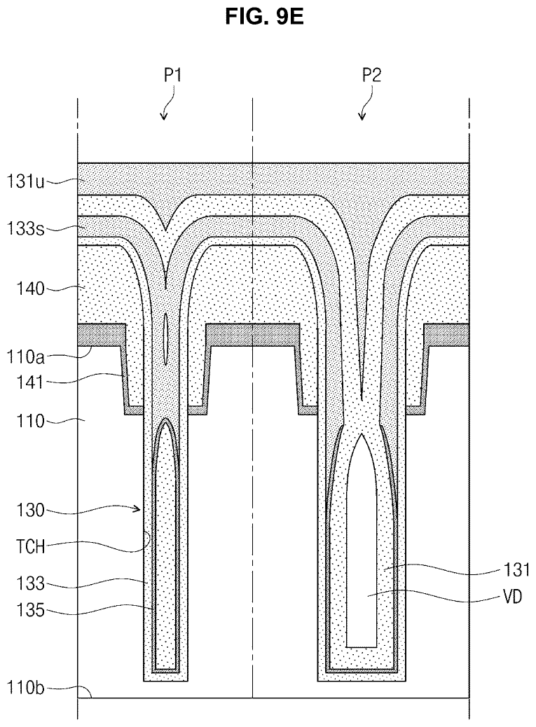

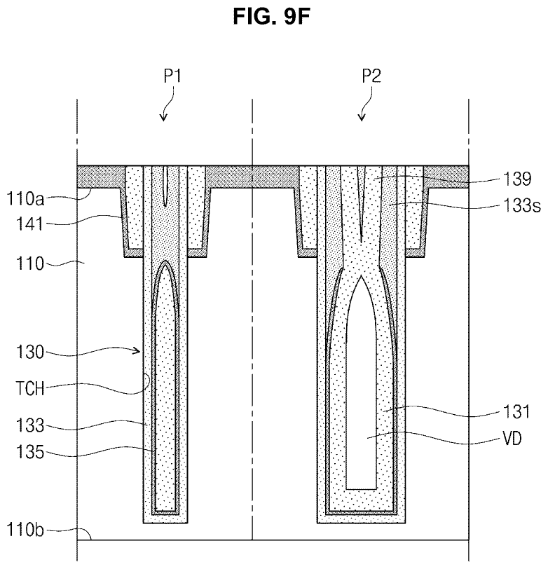

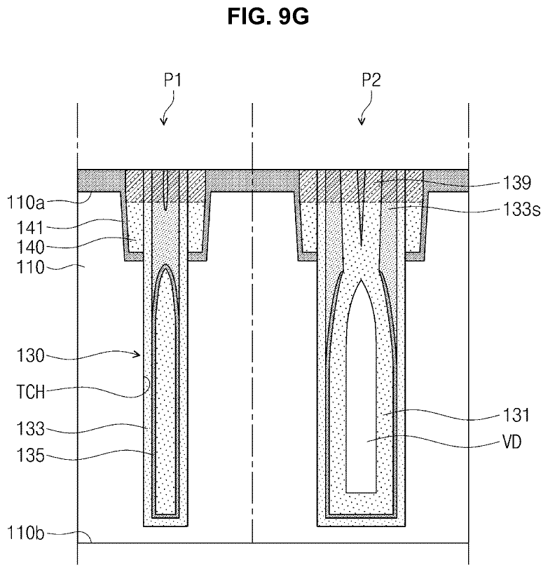

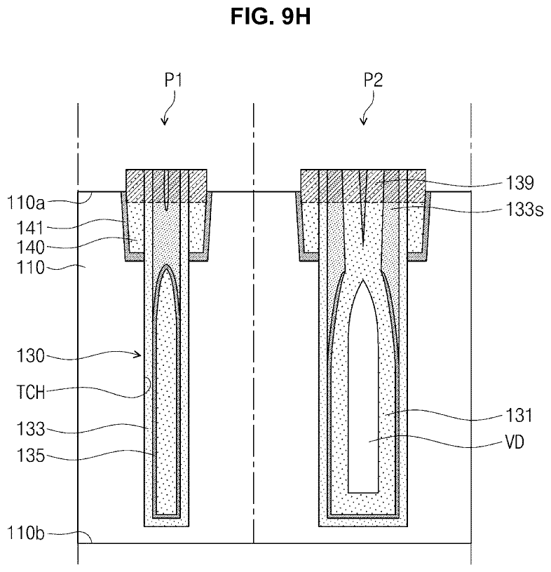

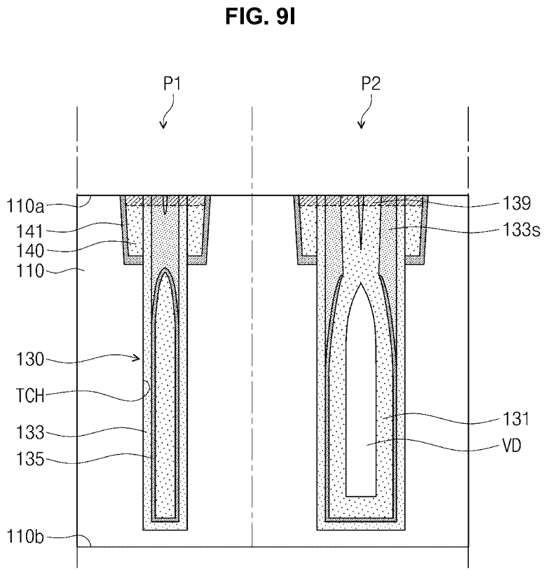

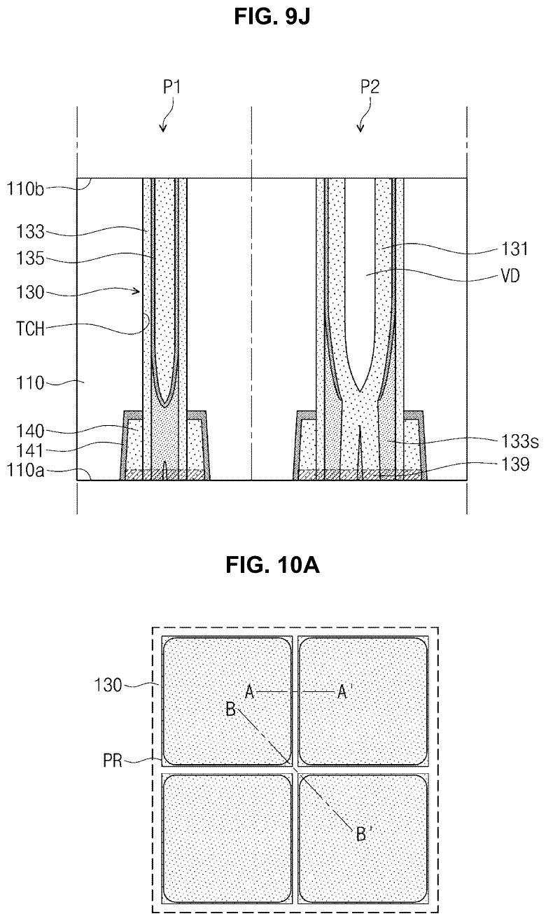

FIGS. 9A to 9J are cross-sectional views sequentially illustrating the process of fabricating the image sensor according to some example embodiments of the present disclosure, and views corresponding to parts P1 and P2 of FIG. 4. The process of fabricating the image sensor according to some example embodiments of the present disclosure will be described by making reference to the above-described embodiments for the illustrative purpose, and the duplication of the above description will be omitted.

Referring to FIG. 9A, the semiconductor substrate 110 including the first surface 110a and the second surface 110b opposite to each other may be provided. In the semiconductor substrate 110, the pad layer 141 and the shallow isolation layer 140 may be formed to be adjacent to the first surface 110a, and may be buried into the semiconductor substrate 110. The pad layer 141 and the shallow isolation layer 140 may include an insulating material, and may include a silicon oxide layer, a silicon nitride layer, and/or a silicon oxynitride layer. For example, the pad layer 141 may include a silicon nitride layer, and the shallow isolation layer 140 may include a silicon oxide layer.

The trench TCH is formed on the semiconductor substrate 110 having the shallow isolation layer 140. The trench TCH may have different widths depending on regions. For example, the trench TCH may be formed to have mutually different widths depending on a region for the first isolation layer 130a and a region for the second isolation layer 130b. The width of the trench TCH provided at the crossing part may be greater than the width of the trench TCH provided at the side part.

The trench TCH may extend from the first surface 110a of the semiconductor substrate 110 into the semiconductor substrate 110. The trench TCH is formed by forming a mask pattern for defining a region for the trench TCH corresponding to the region for the isolation layer 130, and etching the pad layer, the shallow isolation layer 140, and the semiconductor substrate 110 by using the mask pattern.

When viewed in a plan view, the trench TCH may surround each pixel PX.

The insulating liner 133 is formed on the semiconductor substrate 110 having the trench TCH. The insulating liner 133 may cover the inner wall of the trench TCH and conformally cover the top surface of the semiconductor substrate 110 having the shallow isolation layer 140. The insulating liner 133 may be formed through various schemes. For example, the insulating liner 133 may be formed through an atomic layer deposition (ALD) scheme.

Referring to FIG. 9B, the support 133s is formed on the inner wall of the trench TCH having the insulating liner 133. The support 133s may be formed in the trench through a deposition scheme which is lower in step coverage.

The support 133s may be formed through various schemes, for example, through a low pressure chemical vapor deposition (LPCVD) scheme. The support 133s may be formed through a middle temperature oxidation (MTO) scheme, or a high temperature oxidation (HTO) scheme using the LPCVD scheme. In some example embodiments, the support 133s may be formed by performing the process employing monosilane (SiH₄+2N₂O->SiO₂) or dysilane (SiH₂Cl₂+4N₂O->SiO₂) at the temperature ranging from about 700 to 800° C. However, the scheme for forming the support 133s is not limited thereto. For example, the support 133s may be formed through a CVD scheme and/or ALD scheme, such as a high density plasma (HDP) scheme, a high aspect ratio process (HARP), or a PE-TEOS, which is low in step coverage.

The supports 133s may make contact with each other on sidewalls adjacent to each other inside the first isolation layer 130a, and may not make contact with each other inside the second isolation layer 130b.

Referring to FIG. 9C, the conductive liner 135 is formed on the semiconductor substrate 110 including the insulating liner 133 and the support 133s. The conductive liner 135 may be formed by forming a layer to conformally cover the inner wall of the insulating liner 133 in the trench TCH and the top surface of the semiconductor substrate 110 in the trench TCH, and removing an upper portion of the inner wall of the insulating liner 133 in the trench TCH, and a portion of the top surface of the semiconductor substrate 110.

The conductive liner 135 may include a semiconductor material, which is doped with impurities in a first conductive type or a second conductive type, for example, polycrystalline silicon doped with boron or phosphorus.

According to some example embodiments of the present disclosure, the conductive liner 135 may be formed by doping impurities into in-situ Boron Doped Silicon, in-situ Phosphorus Doped Silicon, or undoped silicon in a gas phase through an LPCVD scheme. The conductive liner 135 may employ N type impurities or P type impurities for conductivity.

The conductive liner 135 may be formed by using at least one of a process (e.g., an LPCVD or a PECVD) of mixing and depositing a semiconductor material with impurities, or a process (e.g., ion implantation, plasma doping, or gas phase doping) of implanting impurities after depositing a semiconductor material. In this process, silicon seed treatment may be first performed through Diisopropylamino Silane (DIPAS) and/or Hexachorodisilane (HCDS) before depositing materials of the conductive liner 135, such that the conductive liner 135 is conformally formed in the trench TCH.

In some example embodiments, the conductive liner 135 may include a doped silicon material, but the present disclosure is not limited thereto. The conductive liner 135 may include conductive metal, an organic conductive material, or an inorganic conductive material.

According to some example embodiments of the present disclosure, the conductive liner 135 may be conformally formed in the first and second isolation layers 130a and 130b. Regarding the first isolation layer 130a, even if the supports 133s face each other, the material for the conductive liner 135 may be deposited to the inner side of the first isolation layer 130a through an open part of the second isolation layer 130b.

Next, the upper portion of the conductive liner 135 may be removed through the etching process. The conductive liner 135 on a region, which corresponds to the depth of the shallow isolation layer 140, in a region for the support 133s may be removed through an in-situ process or an ex-situ process.

Referring to FIG. 9D, the buried insulating pattern 131 is formed in the trench TCH having the conductive liner 135. The buried insulating pattern 131 may cover the top surface of the semiconductor substrate 110. The buried insulating pattern 131 may be formed through various processes such as an atomic layer deposition process, a fluid chemical vapor deposition process, or a physical vapor deposition process.

The buried insulating pattern 131 may include a material having no conductivity and excellent gap-fill properties. For example, the buried insulating pattern 131 may be formed by using tonene silazene (TOSZ), undoped silicate glass (USG), borosilicate glass (BSG), phosphosilicate glass (PSG), borophosphosilicate glass (BPSG), plasma enhanced tetra ethyl ortho silicate (PETEOS), fluoride silicate glass (FSG), Tetraethyl orthosilicate (O₃-TEOS), or plasma enhanced tetra ethyl ortho silicate (PETEOS). However, the buried insulating pattern 131 is not limited thereto. For example, the buried insulating pattern 131 may include a silicon nitride and/or a silicon oxynitrde, and an oxide film including silicon oxide.

When the buried insulating pattern 131 is formed in the trench TCH, the cavity VD such as an air gap may be formed in the trench TCH. The cavity VD may or may not be formed in the trench TCH. The cavity VD may be formed to be larger when the width of the trench TCH is large. Accordingly, the cavity VD formed in the trench TCH for the second isolation layer 130b may be more increased, as compared to the cavity VD formed in the trench TCH for the first isolation layer 130a. Although FIG. 9D illustrates that adjacent side surfaces of the buried insulating pattern 131 make contact with each other at the crossing part, the adjacent side surfaces of the buried insulating pattern 131 may not make contact with each other at the crossing part depending on the width of the trench TCH.

Referring to FIG. 9E, an upper buried insulating pattern 131u may be further formed on the semiconductor substrate on which the buried insulating layer is formed, and then the upper buried insulating pattern 131u may be annealed.

Referring to FIG. 9F, an upper portion of the first surface 110a of the semiconductor substrate 110 may be removed. The upper portion of the first surface 110a of the semiconductor substrate 110 may be removed through a chemical mechanical polishing (CMP) process, an etching process, or a chemical mechanical polishing and etching process. As the etching process is performed, some of components on the semiconductor substrate 110 may be further removed.

In some example embodiments, the chemical mechanical polishing process or the etching process may be performed until the shallow isolation layer 140 and the pad layer 141 of the semiconductor substrate 110 are exposed to the outside. Accordingly, the top surface of the shallow pad layer 141, the top surface of the isolation layer 140, the top surface of the insulating liner 133, and the top surface of the support 133s, and the top surface of the buried insulating pattern 131 may be exposed to the outside, and the top surfaces of the components exposed to the outside may be coplanar with each other.

Although not illustrated, the pixels of the photoelectric conversion region PD may be formed in the semiconductor substrate 110. The forming of the photoelectric conversion region PD may include implanting impurities in the second conductive type different from the first conductive type (e.g., the P type) into the semiconductor substrate 110.

Referring to FIG. 9G, after the impurities are doped into the upper portion of the isolation layer 130, an annealing treatment is performed to form the etching barrier layer 139.

The process of doping the impurities is performed by performing an ion implanting process of the impurities, such as B, C, N, Ar, He, Si, As, P, BF_{2/3}, or Sb, for the first surface of the semiconductor substrate. However, the process of doping the impurities is not limited thereto. The process of doping the impurities may employ a plasma doping (PLAD) process or a gas phase doping (GPD) process.

The isolation layer 130 doped with impurities may be densified by selectively performing the annealing process. The annealing process may be performed in a furnace at the temperature ranging from about 450° C. to about 1250° C. for a time ranging from about 10 minutes to about 180 minutes. For example, the annealing treatment may be performed in the furnace at the temperature of about 700° C. for about 10 minutes. However, the annealing treatment is not limited thereto. The annealing treatment may be performed through various scheme such as Rapid Thermal Process/Anneal (RTP/A), Spike Anneal (sRTP), Flash Anneal (fRTP), or laser anneal (LSA).

When the impurities are doped through the ion implanting process, the projected range (Rp) for ion-implanting is adjusted to control a doping depth. According to some example embodiments of the present disclosure, the projected range (Rp) for ion-implanting may be performed with the depth of about 1 Å to 1800 Å from the top surface of the exposed semiconductor substrate. Alternatively, the projected range for the ion-implanting may have the depth corresponding to about 70% or less of the shallow isolation layer 140.

Referring to FIG. 9H, the pad layer 141 is selectively removed and the first surface 110a of the semiconductor substrate 110 is exposed to the outside. The selectively removing of the pad layer 141 is performed due to the difference in etch rate between the part of the etching barrier layer 139 formed on the insulating liner 133 and another component, especially, the pad layer 141. In some example embodiments, only the pad layer 141 may be removed through the etching process.

According to some example embodiments of the present disclosure, various etch rates may be employed depending on a material constituting a component to be etched, a condition of impurities, and the state of annealing treatment. In particular, the isolation layer 130, which is doped, formed on the semiconductor substrate 110 and components other than the isolation layer 130 may be etched at various etch rates depending to etchants used based on materials. For example, the higher etch rate is provided for hydrofluoric acid-based etchant in the case of an oxide-based insulating layer. The higher etch rate is provided for phosphoric acid-based etchant in the case of a nitride-based insulating layer.

According to some example embodiments of the present disclosure, when a specific component (e.g., the pad layer 141) is removed using a specific etchant, corrosion resistance is improved through doping, thereby reducing (and/or minimizing) the loss of the insulating material in the isolation layer 130. According to some example embodiments of the present disclosure, as impurities are doped into the isolation layer 130, the isolation layer 130 may exhibit the greater corrosion resistance, and may require lower etch rate, as compared to the pad layer 141.

The portion of the isolation layer 130 on which the etching barrier layer 139 is formed due to the etching of the pad layer 141 may protrude from the first surface 110a of the semiconductor substrate 110.

Referring to FIG. 9I, a top surface of the portion, which protrudes, of the isolation layer 130 may be sequentially removed until the top surface of the portion, which protrudes, of the isolation layer 130 becomes coplanar with the first surface 110a through the subsequent process of forming the circuit wiring layer.

Although the circuit wiring layer is not disposed in FIG. 9I, the gate pattern and the circuit wiring layer including the gate insulating layer may be formed on the first surface 110a. The interlayer insulating layer 210, the contact via 230, and the conductive lines 220 may be formed on the first surface 110a.

Referring to FIG. 9J, the semiconductor substrate 110 is upside down such that the second surface 110b is positioned up, and a thin-film process may be performed with respect to the upper portion of the second surface 110b of the semiconductor substrate 110. A portion of the second surface 110b of the semiconductor substrate 110 may be removed through the thin-film process. The second surface 110b of the semiconductor substrate 110 may be removed through a chemical mechanical polishing (CMP) process, an etching process, or a chemical mechanical polishing and etching process The second surface 110b of the semiconductor substrate 110 may be coplanar with the top surfaces of the conductive liner 135, the insulating liner 133, and the buried insulating pattern 131 of the isolation layer 130.

According to some example embodiments of the present disclosure, the second surface 110b of the semiconductor substrate 110 is exposed through the process, and the top surface of the first isolation layer 130a and the second isolation layer 130b may be coplanar with the second surface 110b of the semiconductor substrate 110.

Thereafter, although not illustrated, the upper insulating layer 310 is formed on the second surface 110b of the semiconductor substrate 110 having the first isolation layer 130a and the second isolation layer 130b. The upper insulating layer 310 may include an anti-reflective layer. When the upper insulating layer is formed, insulating materials forming the upper insulating layer 310 may be filled in the cavity VD formed at the crossing part. The color filters CF, the fence pattern 320, an insulating layer 330, the micro-lenses ML, and the passivation layer 340 are formed on the semiconductor substrate 110 having the upper insulating layer 310.

The image sensor according to some example embodiments of the present disclosure may be formed through the above procedure. The present disclosure is not limited to the above-described embodiment, and may be formed through another method.

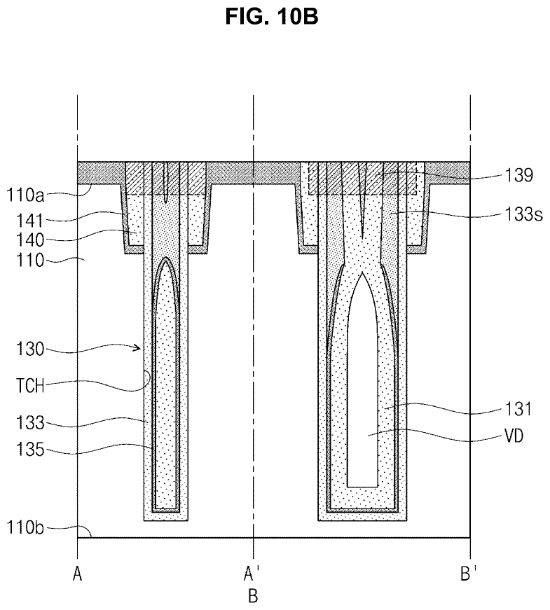

FIGS. 10A and 10B illustrate that impurities are locally doped only into a partial region, instead of that the impurities are doped into the entire surface of the semiconductor substrate. FIG. 10A is a plan view illustrating four pixels adjacent to each other, and FIG. 10B are cross-sectional views taken along line A-A′ and B-B′ of FIG. 10A.

Referring to FIGS. 10A and 10B, the impurities may be doped only into a region to be doped with impurities using a photoresist pattern or a hard mask.

For example, as illustrated in FIGS. 10A and 10B, the photoresist pattern PR is formed in a region other than the isolation layer 130, without being formed on the isolation layer 130. When the impurities are implanted by using the photoresist pattern PR as the mask, the impurities are doped only into the isolation layer 130. Accordingly, the etching barrier layer may be effectively formed only on the isolation layer 130.

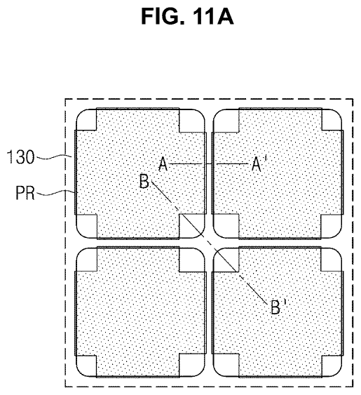

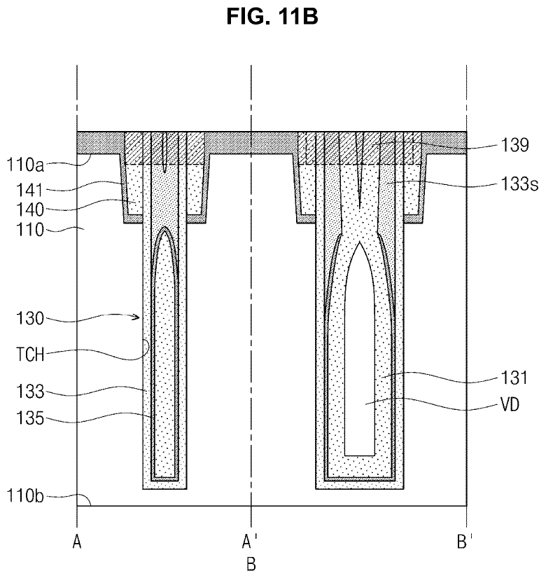

FIGS. 11A and 11B illustrate that impurities are locally doped only into a partial region, instead of that the impurities are doped into the entire surface of the semiconductor substrate. FIG. 11A is a plan view illustrating four pixels adjacent to each other, and FIG. 11B are cross-sectional views taken along line A-A′ and B-B′ of FIG. 11A.

Referring to FIGS. 11A and 11B, the impurities are doped into only a region to be doped with impurities using the photoresist pattern PR or the hard disk, and the photoresist pattern PR may be formed on the crossing region in which the loss of the insulating layer is significantly caused. For example, a wider open area of photoresist pattern PR is located in the region corresponding to the crossing part. Accordingly, the etching barrier layer is formed at a sufficient extent in the device isolation layer 130,

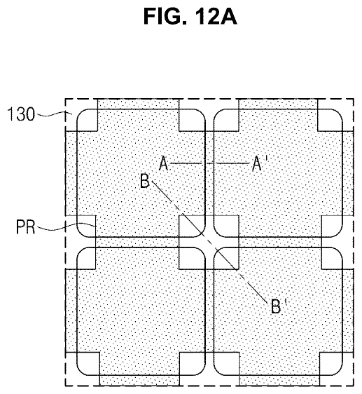

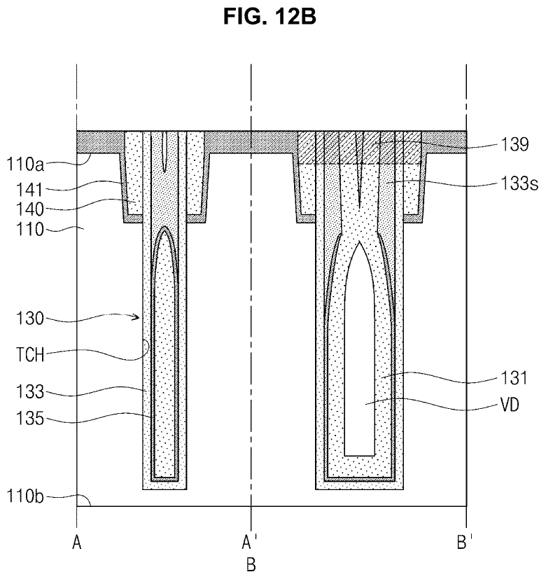

FIGS. 12A and 12B illustrate that impurities are locally doped only into a partial region, instead of that the impurities are doped into the entire surface of the semiconductor substrate. FIG. 12A is a plan view illustrating four pixels adjacent to each other, and FIG. 12B are cross-sectional views taken along line A-A′ and B-B′ of FIG. 12A.

Referring to FIGS. 12A and 12B, the impurities may be doped only into a region to be doped with impurities using a photoresist pattern PR or a hard mask. In some example embodiments, only the crossing part is doped. The entire portion of the first isolation layer positioned at the side part is covered with the photoresist pattern PR. Accordingly, the impurities are not doped into the first isolation layer, so the etching barrier layer is not formed on the first isolation layer. The second isolation layer positioned at the crossing part has no photoresist pattern PR. Accordingly, the impurities are doped into the second isolation layer, and the etching barrier layer is formed on the top surface of the second isolation layer.

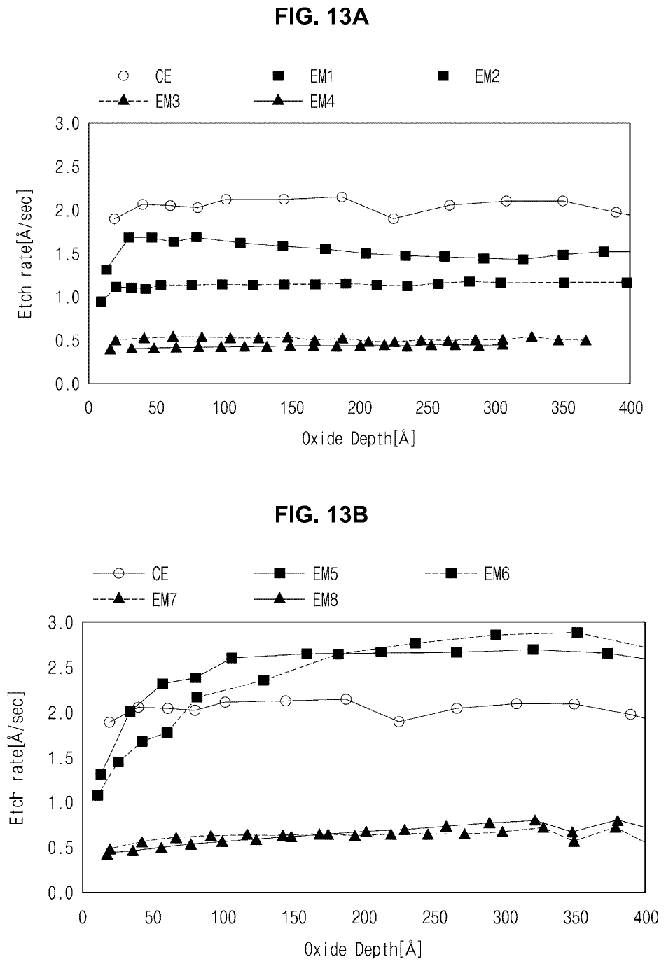

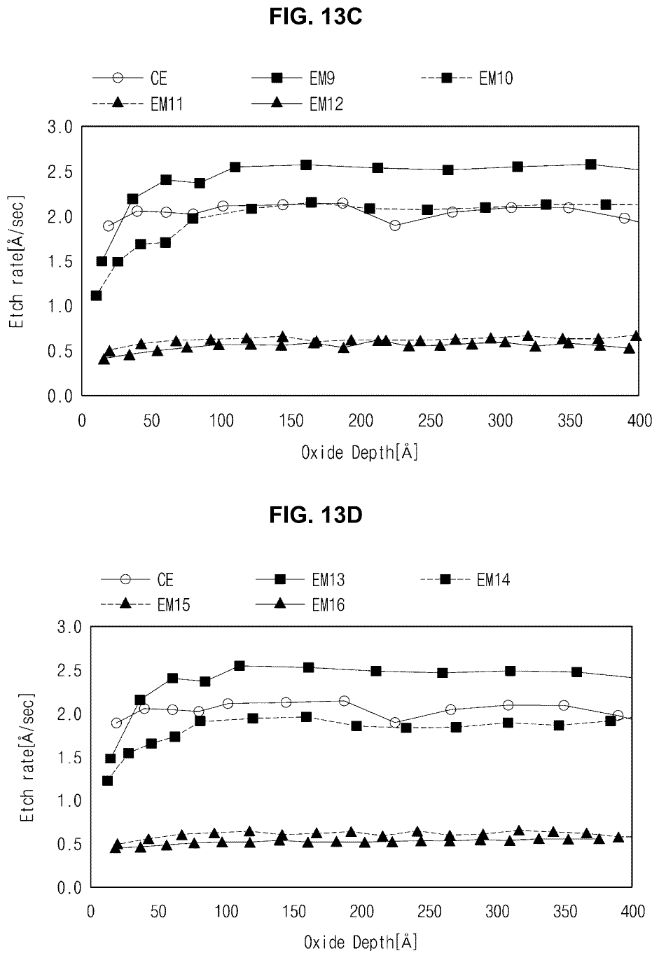

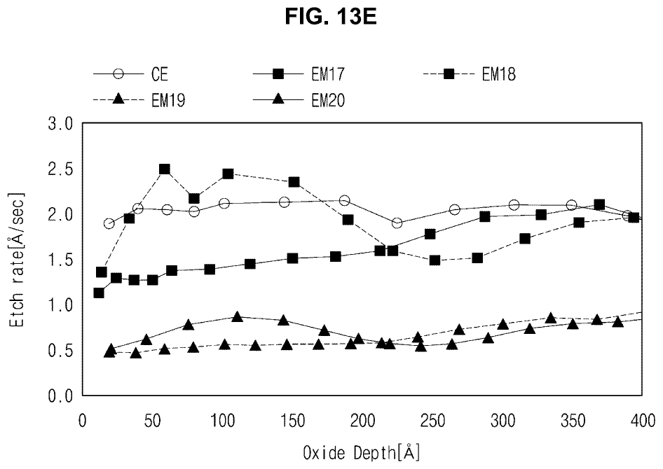

As described above, the impurities are doped only into the region for reducing (and/or minimizing) the etching for the insulating layer using photoresist or a hard mask, thereby reducing (and/or minimizing) the loss of the insulating layer. The experimental result of reducing (and/or minimizing) the loss of the insulating layer by the etching barrier layer 139 is illustrated in FIGS. 13A to 13E.

FIGS. 13A to 13E are graphs illustrating the etch rate when impurities are doped into the insulating material constituting the insulating layer. As illustrated in FIGS. 13A to 13E, the material for the doping was a silicon oxide, and hydrofluoric acid was used as the etchant. The silicon oxide, which is not doped, was marked with ‘CE’ according to a comparative example. According to some example embodiments, the doped silicon oxide was marked with Embodiment 1 (EM1) to Embodiment 20 (EM20).

Each etch rate was measured under the same condition except for the type of impurities, a doping amount, and the state of annealing treatment. The type of impurities, the doping amount, and the state of the annealing treatment are as follows under each condition.

TABLE 1

| | | | Doping amount | Annealing |
|---|---|---|---|---|
| Classification | Sign | Impurities | (/cm³) | treatment |
| Comparative | CE | — | — | — |
| example | | | | |
| Embodiment 1 | EM1 | B | 1.0 × 10¹⁵ | X |
| Embodiment 2 | EM2 | B | 5.0 × 10¹⁵ | X |
| Embodiment 3 | EM3 | B | 1.0 × 10¹⁵ | ◯ |
| Embodiment 4 | EM4 | Ar | 5.0 × 10¹⁵ | ◯ |
| Embodiment 5 | EM5 | Ar | 1.0 × 10¹⁵ | X |
| Embodiment 6 | EM6 | Ar | 5.0 × 10¹⁵ | X |
| Embodiment 7 | EM7 | Ar | 1.0 × 10¹⁵ | ◯ |
| Embodiment 8 | EM8 | Ar | 5.0 × 10¹⁵ | ◯ |
| Embodiment 9 | EM9 | C | 1.0 × 10¹⁵ | X |
| Embodiment 10 | EM10 | C | 5.0 × 10¹⁵ | X |
| Embodiment 11 | EM11 | C | 1.0 × 10¹⁵ | ◯ |
| Embodiment 12 | EM12 | C | 5.0 × 10¹⁵ | ◯ |
| Embodiment 13 | EM13 | Si | 1.0 × 10¹⁵ | X |
| Embodiment 14 | EM14 | Si | 5.0 × 10¹⁵ | X |
| Embodiment 15 | EM15 | Si | 1.0 × 10¹⁵ | ◯ |
| Embodiment 16 | EM16 | Si | 5.0 × 10¹⁵ | ◯ |
| Embodiment 17 | EM17 | BF₃ | 1.0 × 10¹⁵ | X |
| Embodiment 18 | EM18 | BF₃ | 5.0 × 10¹⁵ | X |
| Embodiment 19 | EM19 | BF₃ | 1.0 × 10¹⁵ | ◯ |
| Embodiment 20 | EM20 | BF₃ | 5.0 × 10¹⁵ | ◯ |

Referring to FIGS. 13A to 13E, when the impurities are doped into the silicon oxide, the etch rate was reduced by about 70% or more, as compared to that the impurities are not doped into the silicon oxide. Even when the impurities are doped into the silicon oxide, when a doping amount is greater than or equal to a specific amount, the etch rate was remarkably decreased in the most cases. In particular, for boron, the etch rate was reduced by 40% or more without the annealing treatment. It may be recognized that the annealing treatment more reduces the etch rate, as compared to the annealing treatment is not performed.

According to embodiments of the present disclosure, when the image sensor is fabricated, the loss of the insulating layer, which is caused in the isolation layer, is reduced (and/or minimized). The isolation layer may include various insulating materials, for example, an insulating material such as a silicon oxide, as described above. However, when another component is formed after the isolation layer is formed, the insulating layer may be unintentionally etched by a wet etchant for cleaning. The wet etchant for cleaning may include a buffer oxide etchant (BOE; the mixture of NH₄F; the mixture of HF) and SC1 (NH₄OH, H₂O₂ and H₂O mixture). The isolation layer has a top surface which is irregularly formed through the unintentional etching of the insulating layer, which causes the defect of the structure when another component of the image sensor is formed. In particular, according to a recent technology having the tendency of reducing the size of the image sensor and increasing the number of pixels, as the aspect ratio of the isolation layer is increased, the cavity having the seam shape may be formed when the insulating material of the isolation layer is filled, even if the insulating material having the large gap fill characteristics is used. The insulating material constituting the isolation layer has a low corrosion resistance, so the loss of the insulating material is accelerated when the subsequent process is performed. According to the present disclosure, the etching barrier layer 139 is formed in the device isolation, thereby reducing (and/or minimizing) the loss of the insulating material, which is caused in the isolation layer. Accordingly, defects may be limited and/or prevented from being caused due to the loss of the insulating material.

As described above, according to some example embodiments of the present disclosure, the conductive isolation layer having reduced (and/or minimized) light absorption may be formed, thereby reducing (and/or minimizing) the light loss of the image device. The negative bias may be applied to the isolation layer, thereby reducing (and/or minimizing) defects such as the dark current.

According to some example embodiments of the present disclosure, in the process for the image sensor, the structure of limiting and/or preventing the material constituting the isolation layer from being lost is employed, thereby reducing (and/or minimizing) defects resulting from the loss in the material constituting the isolation layer.

Although some example embodiments of the present disclosure have been described for illustrative purposes, those skilled in the art will appreciate that various modifications, and substitutions are possible, without departing from the scope and spirit of the inventive concepts as disclosed in the accompanying claims.

Accordingly, the technical scope of the present disclosure is not limited to the detailed description of this specification, but should be defined by the claims.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. An image sensor comprising:
a semiconductor substrate including a plurality of pixels, the semiconductor substrate having a first surface and a second surface opposite to the first surface, and the semiconductor substrate having a trench formed through the first surface and the second surface;
an isolation layer in the trench, the isolation layer configured to isolate the pixels from each other; and
an etching barrier layer in the isolation layer, the etching barrier layer having a first depth from the first surface of the semiconductor substrate,
wherein the isolation layer includes
an insulating liner covering a sidewall of the trench, the insulating liner passing from the first surface to the second surface,
a support covering at least a portion of a sidewall of the insulating liner, and
a conductive liner inside the trench, the conductive liner contacting the insulating liner and the support, and
wherein the etching barrier layer has a corrosion resistance higher than a corrosion resistance of a region of the semiconductor substrate other than the etching barrier layer.

2. The image sensor of claim 1, wherein the isolation layer includes an insulating material in a region adjacent to the first surface, and the etching barrier layer comprises the insulating material having impurities doped therein.

3. The image sensor of claim 2, wherein the impurities include
at least one of B, C, N, Ar, He, Si, As, P, BF₂, BF₃, or Sb.

4. The image sensor of claim 3, wherein the impurities have a doping concentration ranging from 1.0×10¹⁴/cm² to 2.0×10¹⁶/cm².

5. The image sensor of claim 2, wherein the etching barrier layer has a thickness ranging from 1 Å to 1800 Å.

6. The image sensor of claim 2, further comprising:
a shallow isolation layer buried in the semiconductor substrate, the shallow isolation layer extending from the first surface,
wherein the first depth of the etching barrier layer is 70% or less of a depth of the shallow isolation layer.

7. The image sensor of claim 2, wherein the insulating liner and the support include the insulating material, and
wherein the etching barrier layer is in a portion of the insulating liner and a portion of the support.

8. The image sensor of claim 6, wherein a sum of a width of the insulating liner adjacent to the first surface and a width of the support, is greater than a width of the insulating liner adjacent to the second surface.

9. The image sensor of claim 2, wherein the plurality of pixels are arranged in a form of a matrix in a plan view, and
wherein the isolation layer includes,
a first isolation layer at side parts of the plurality of pixels, the side parts extending in a row direction and a column direction of the matrix; and
a second isolation layer at crossing parts at which the side parts cross each other along the row and column directions.

10. The image sensor of claim 9, wherein the conductive liner at the second isolation layer comprises respective second conductive liners that surround peripheral portions of second respective pixels from among the plurality of pixels, the respective second conductive liners being spaced apart from each other between pixels from among the second respective pixels that are adjacent to each other, and
the conductive liner at the first isolation layer comprises respective first conductive liners that surround peripheral portions of first respective pixels from among the plurality of pixels, the respective first conductive liners being connected to each other between pixels from among the first respective pixels that are adjacent to each other.

11. The image sensor of claim 10, wherein the conductive liner is connected to a negative bias voltage.

12. The image sensor of claim 9, further comprising:
a buried insulating pattern filled in the trench, the buried insulating pattern covering the conductive liner and the support.

13. The image sensor of claim 12, wherein the buried insulating pattern defines a cavity therein, and
wherein the cavity is filled with at least one of air and the insulating material.

14. The image sensor of claim 13, wherein the insulating material filled in the cavity is at least one of hafnium oxide, zirconium oxide, titanium oxide, aluminum oxide, silicon oxide, tantalum oxide, or plasma enhanced-tetra ethylene orthosilicate.

15. The image sensor of claim 9, further comprising:
a buried conductive pattern filled in the trench, the buried conductive pattern covering the conductive liner and the support.

16. The image sensor of claim 15, wherein the buried conductive pattern is in the second isolation layer.

17. An image sensor comprising:
a semiconductor substrate including a plurality of pixels, the semiconductor substrate having a first surface and a second surface opposite to the first surface, and the semiconductor substrate having a trench formed through from the first surface to the second surface;
a micro-lens on the second surface;
an isolation layer in the trench, the isolation layer configured to isolate the plurality of pixels from each other; and
an etching barrier layer in the isolation layer, the etching barrier layer having a first depth from the first surface of the semiconductor substrate,
wherein the isolation layer includes
an insulating liner covering a sidewall of the trench, the insulating liner passing from the first surface to the second surface,
a conductive liner covering at least a portion of a sidewall of the insulating liner,
a support contacting the insulating liner and the conductive liner, the support being at an inner part of the trench that is adjacent to the first surface, and
a buried insulating pattern or a buried conductive pattern filled in the trench and covering the conductive liner and the support, and
wherein the etching barrier layer is doped with impurities to have a corrosion resistance higher than a corrosion resistance of a region of the semiconductor substrate other than the etching barrier layer.

18. A method for fabricating an image sensor, the method comprising:
preparing a semiconductor substrate having a first surface and a second surface opposite to the first surface, and a photoelectric conversion region in the semiconductor substrate;
forming a trench through the first surface and the second surface of the semiconductor substrate;
forming an insulating liner in the trench;
forming a support in the trench on the insulating liner;
forming a conductive liner in the trench, the conductive liner covering the support;
filling a buried insulating pattern or a buried conductive pattern in the trench on the conductive liner;
removing a portion of the insulating liner, the support, and the buried insulating pattern or the buried conductive pattern;
forming an etching barrier layer by implanting impurities into remaining portions of the insulating liner, the support, and the buried insulating pattern or the buried conductive pattern; and
etching a portion of the semiconductor substrate including the etching barrier layer.

19. The method of claim 18, further comprising:
performing an annealing treatment on the etching barrier layer implanted with the impurities.

20. The method of claim 18, wherein the forming of the etching barrier layer by implanting the impurities includes:
forming a photoresist pattern on at least a portion of the semiconductor substrate; and
implanting the impurities using the photoresist pattern as a mask.
